(19) United States
(12) Patent Application Publication
(10) Pub. No.: US 2026/0039248 A1
(43) Pub. Date: Feb. 5, 2026

(54) OSCILLATOR CIRCUITRY FOR ISOLATED SYSTEMS

(71) Applicant: Texas Instruments Incorporated, Dallas, TX (US)

(72) Inventors: Kumar Anurag Shrivastava, Bangalore (IN); Udita Mukherjee, Bangalore (IN)

(21) Appl. No.: 18/790,784

(22) Filed: Jul. 31, 2024

(51) Int. Cl. H03B 5/12

(52) U.S. Cl. CPC H03B 5/1215; H03B 5/1228

(57) ABSTRACT

An example apparatus includes: first oscillator circuitry having a first terminal, a second terminal, and including a first transistor having a first threshold voltage; second oscillator circuitry having a first terminal, a second terminal, and including a second transistor having a second threshold voltage, the second threshold voltage is less than the first threshold voltage; a first resistor having a first terminal and a second terminal, the first terminal of the first resistor coupled to the first terminal of the first oscillator circuitry and the first terminal of the second oscillator circuitry; a second resistor having a first terminal and a second terminal, the first terminal of the second resistor coupled to the second terminal of the first oscillator circuitry and the second terminal of the second oscillator circuitry; and a common terminal coupled to the second terminal of the first resistor and the second terminal of the second resistor.

### TECHNICAL FIELD

This description relates generally to digital isolation and, more particularly, to methods and apparatus for oscillator circuitry in isolated systems.

### BACKGROUND

As electronics continue to advance, systems can safely operate at increasingly complex operating conditions, such as higher powers and higher speeds. In isolated systems, isolation circuitry implements advanced techniques to transmit data across an isolation barrier at increasing speeds. Such circuitry allows isolated systems to precisely transmit data across isolation barriers at higher speeds despite complex operating conditions.

### SUMMARY

For methods and apparatus for oscillator circuitry in isolated systems, an example apparatus includes first current source circuitry having a terminal; second current source circuitry having a terminal; a first transistor having a first terminal, a second terminal, and a control terminal; a second transistor having a first terminal, a second terminal, and a control terminal, the first terminal of the second transistor coupled to the terminal of the first current source circuitry and the first terminal of the first transistor; a third transistor having a first terminal, second terminal, and a control terminal; a fourth transistor having a first terminal, a second terminal, and a control terminal, the first terminal of the fourth transistor coupled to the terminal of the second current source circuitry and the first terminal of the third transistor; and inductor circuitry having a first terminal and a second terminal, the first terminal of the inductor circuitry coupled to the second terminal of the first transistor, the control terminal of the second transistor, the second terminal of the third transistor, and the control terminal of the fourth transistor, the second terminal of the inductor circuitry coupled to the control terminal of the first transistor, the second terminal of the second transistor, the control terminal of the third transistor, and the second terminal of the fourth transistor. Other examples are described.

For methods and apparatus for oscillator circuitry in isolated systems, an example apparatus includes first oscillator circuitry having a first terminal, a second terminal, and including a first transistor having a first threshold voltage; second oscillator circuitry having a first terminal, a second terminal, and including a second transistor having a second threshold voltage, the second threshold voltage is less than the first threshold voltage; a first resistor having a first terminal and a second terminal, the first terminal of the first resistor coupled to the first terminal of the first oscillator circuitry and the first terminal of the second oscillator circuitry; a second resistor having a first terminal and a second terminal, the first terminal of the second resistor coupled to the second terminal of the first oscillator circuitry and the second terminal of the second oscillator circuitry; and a common terminal coupled to the second terminal of the first resistor and the second terminal of the second resistor. Other examples are described.

For methods and apparatus for oscillator circuitry in isolated systems, an example apparatus includes a first transistor having a first terminal, a second terminal, and a control terminal; a second transistor having a first terminal, a second terminal, and a control terminal, the first terminal of the second transistor coupled to the first terminal of the first transistor; a third transistor having a first terminal, a second terminal, and a control terminal; a fourth transistor having a first terminal, a second terminal, and a control terminal, the first terminal of the fourth transistor coupled to the first terminal of the third transistor; a first resistor having a first terminal and a second terminal, the first terminal of the first resistor coupled to the second terminal of the first transistor, the control terminal of the second transistor, the second terminal of the third transistor, and the control terminal of the fourth transistor; a second resistor having a first terminal and a second terminal, the first terminal of the second resistor coupled to the control terminal of the first transistor, the second terminal of the second transistor, the control terminal of the third transistor, and the second terminal of the fourth transistor; a common terminal coupled to the second terminal of the first resistor and the second terminal of the second resistor. Other examples are described.

### BRIEF DESCRIPTION OF THE DRAWINGS

FIG. 1 is a block diagram of an example isolation system including multiple isolated communication channels that use an isolation transformer to couple example transmitter circuitry and example receiver circuitry across an isolation barrier.

FIG. 2 illustrates an example implementation of the isolation system of FIG. 1.

FIG. 3 is a schematic diagram of an example of the transmitter and LC tank circuitry of FIG. 1 including first example oscillator circuitry and second example oscillator circuitry.

FIG. 4 is a schematic diagram of another example of the transmitter and LC tank circuitry of FIGS. 1 and 3 including bias current circuitry.

FIG. 5 is a schematic diagram of another example of the transmitter and LC tank circuitry of FIGS. 1, 3, and 4 including an isolation resistor.

FIG. 6 is a schematic diagram of yet another example of the transmitter and LC tank circuitry of FIGS. 1, 3, 4, and 5 including compensation circuitry.

FIG. 7 is a schematic diagram of an example of the compensation circuitry of FIG. 6.

FIG. 8 is a flowchart representative of example operations that may be at least one of executed, instantiated, or performed using an example implementation of the transmitter circuitry of FIGS. 1, 3, 4, 5, and 6 to transmit data across an isolation barrier.

FIG. 9 is a plot of example region of operations of the transmitter and LC tank circuitry of FIGS. 1, 3, 4, 5, and 6.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

As electronics continue to advance, systems can safely operate at increasingly complex operating conditions, such as higher powers and higher speeds. In isolated systems, isolation circuitry implements advanced techniques to transmit data across an isolation barrier at increasing speeds. Such circuitry allows isolated systems to precisely transmit data across isolation barriers at higher speeds despite complex operating conditions.

Isolation barriers (e.g., galvanic isolators, capacitive isolators, inductive isolators, and optical isolators) are commonly used to isolate signals from noisy environments (such as a switching circuit, etc.) and isolate circuits operating at one voltage from circuits operating at a different voltage. Some isolator designs include transmitter circuitry, an isolation transformer, and receiver circuitry. The transmitter circuitry modulates an input signal onto a carrier signal that traverses the isolation transformer. The isolation transformer includes first inductor circuitry, which is electrically coupled to the transmitter circuitry, and second inductor circuitry, which is electrically coupled to the receiver circuitry. The transmitter circuitry causes the modulated signal to traverse the isolation transformer. The receiver circuitry receives the modulated signal after traversing the isolation transformer.

In some designs, the transmitter circuitry uses on-off keying (OOK) modulation to modulate input signals onto a sinusoidal carrier signal. On-off keying is a process of controlling generation of a sinusoidal signal based on a logic state of the input signal. For example, when the logic state of the input signal is a logic zero, the transmitter circuitry turns off oscillator circuitry to prevent generation of the sinusoidal signal. Further, when the logic state of the input signal is a logic one, the transmitter circuitry turns on the oscillator circuitry to generate the sinusoidal signal, which traverses the isolation transformer.

To implement OOK modulation, transmitter circuitry includes current source circuitry and a cross-coupled pair of transistors, and is coupled to inductor capacitor (LC) tank circuitry. In such designs, the input signal controls the current source circuitry that supplies current to the cross-coupled pair of transistors. When the input signal turns on the current source circuitry, the cross-coupled pair of transistors supply current to the LC tank circuitry. The LC tank circuitry generates a sinusoidal signal responsive to the current from the cross-coupled pair of transistors. As long as the current source remains on, the amplitudes of the sinusoidal signal control the cross-coupled pair of transistors, which regulates a future supply of current to the LC tank circuitry. However, currents through the cross-coupled pair of transistors have a relatively large swing responsive to ringing of the LC tank circuitry. Such changes in currents through the cross-coupled pair of transistors generate excessive noise, which increases emissions.

Some designs separate the inductance of the inductor circuitry into two separate inductors that are coupled to ground to increase immunity to common mode transients. Such a technique may be referred to as center tapping the inductor circuitry. However, the additional ground path to the inductor circuitry increases the magnitude of currents circulating through the transmitter circuitry, which increases emissions. Also, mismatches between the inductors create first harmonic noise that increases emissions.

Examples described herein include methods and apparatus to improve oscillator designs in isolated systems using intentional resistors and multiple cross-coupled pairs of transistors. In some described examples, transmitter circuitry includes first oscillator circuitry, second oscillator circuitry, first LC tank circuitry, and second LC tank circuitry. The first oscillator circuitry includes first current source circuitry and a first cross-coupled pair of transistors. The second oscillator circuitry includes second current source circuitry and a second cross-coupled pair of transistors. The first LC tank circuitry includes a first inductor, a first capacitor, and a first intentional resistor. The second LC tank circuitry includes a second inductor, a second capacitor, and a second intentional resistor. The first and second intentional resistors are coupled in parallel with the first and second inductors. Advantageously, the first and second intentional resistors reduce asymmetries between the first and second inductors by reducing mismatches between equivalent resistances of the first and second inductors. Advantageously reducing mismatches between the first and second inductors reduces noise and decreases radiated emissions.

The first and second oscillator circuitry generate a sinusoidal signal by supplying current to the first and second LC tank circuitry. The first and second oscillator circuitry regulate a supply of current from the first and second current source circuitry to control the first and second cross-coupled pair of transistors responsive to the sinusoidal signal. In the described examples, the first cross-coupled pair of transistors are low threshold voltage transistors, and the second cross-coupled pair of transistors are high performance transistors. During generation of the sinusoidal signal, currents of the first and second LC tank circuitry switch the low threshold voltage transistors between saturation mode and linear mode. During generation of the sinusoidal signal, currents of the first and second LC tank circuitry switch the high-performance transistors between a subthreshold mode and a saturation mode.

Advantageously, at least one of the low threshold voltage transistors conduct current throughout the entire cycle of the sinusoidal signal. Advantageously, continuously conducting current using the low threshold voltage transistors reduces tail node disturbances that occur when either transistor is switching. Advantageously, the high-performance transistors have a greater transconductance, which allows for larger currents of the first and second LC tank circuitry. Advantageously, using both the low threshold voltage transistors and the high-performance transistors improves noise immunity by decreasing emissions.

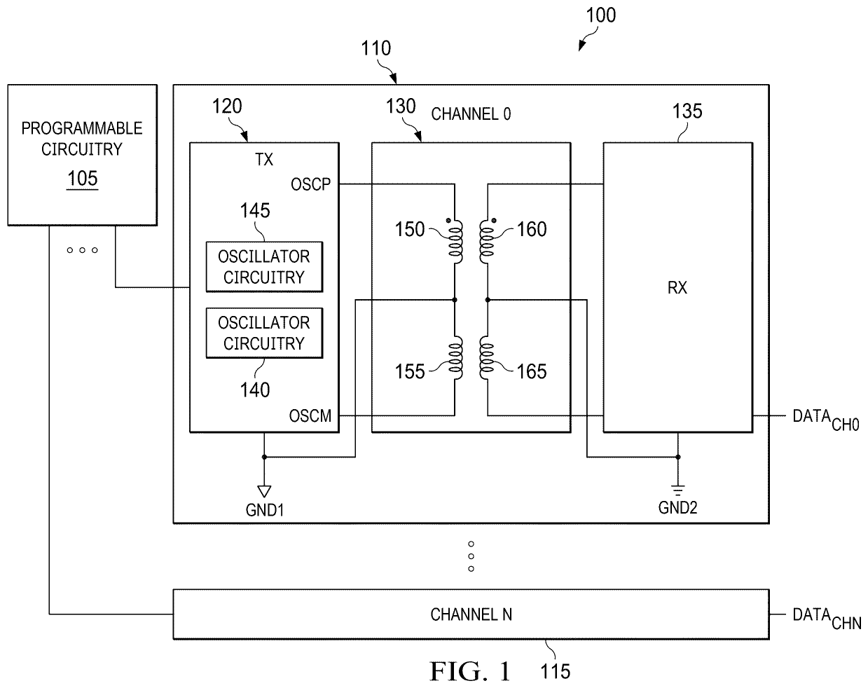

FIG. 1 is a block diagram of an example isolation system 100. In the example of FIG. 1, the isolation system 100 includes programmable circuitry 105, a first communication channel 110, and a second communication channel 115. Alternatively, the isolation system 100 may include any number of instances of the communication channels 110, 115. For example, the isolation system 100 includes four communication channels. The example communication channel 110 of FIG. 1 includes example transmitter circuitry 120, an example isolation transformer 130, and example receiver circuitry 135. The example transmitter circuitry 120 of FIG. 1 includes first example oscillation circuitry 140 and second example oscillation circuitry 145. The example isolation transformer 130 of FIG. 1 includes a first example inductor 150, a second example inductor 155, a third example inductor 160, and a fourth example inductor 165. The isolation system 100 is structured to be coupled to external circuitry, which receives digital signals from the programmable circuitry 105 through the communication channels 110, 115 at data terminals DATA_{CH0}, DATA_{CHN}.

The programmable circuitry 105 has a first terminal and a second terminal. The first terminal of the programmable circuitry 105 is coupled to the communication channel 110. The second terminal of the programmable circuitry 105 is coupled to the communication channel 115. The communication channel 110 has a first terminal and a second terminal (e.g., data terminal DATA_{CH0}). The first terminal of the communication channel 110 is coupled to the programmable circuitry 105. The second terminal of the communication channel 110 is structured to be coupled to external circuitry. The communication channel 115 has a first terminal and a second terminal (e.g., data terminal DATA_{CHN}). The first terminal of the communication channel 115 is coupled to the programmable circuitry 105. The second terminal of the communication channel 115 is structured to be coupled to external circuitry. In some examples, the programmable circuitry 105 is programmable circuitry structured to instantiate circuitry responsive to executing machine readable instructions. In some such examples, the programmable circuitry 105 may be a central processing unit (CPU), graphic processing unit (GPU), microcontroller unit (MCU), field programmable gate array (FPGA), etc.

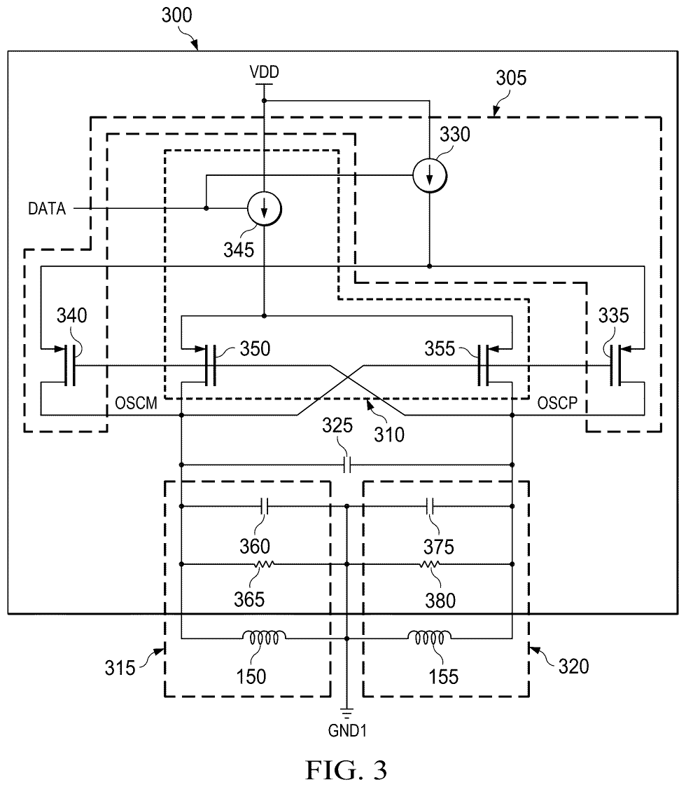

The transmitter circuitry 120 has a first terminal, a second terminal, a third terminal (e.g., OSCP), and a fourth terminal (e.g., OSPM). The first terminal of the transmitter circuitry 120 is coupled to the programmable circuitry 105. The second terminal of the transmitter circuitry 120 is coupled to a first common terminal (GND1), which supplies a first common potential (e.g., ground, AVSS, etc.). In the examples described herein, the common terminal is structured to be coupled (e.g., routed) to a portion of a device packaging that supplies a common potential. In some examples, the first common terminal is structured to be coupled to a conductive layer, which has a potential considered to be common to circuitry of the device (often referred to as ground), by electrical traces. In such examples, the conductive layer that is set to the common potential may be referred to as a ground plane. In the described examples, a common terminal is at least one of a lead, pad, trace, or other component of a package, which may be coupled to a conductive layer set to the common potential. The third and fourth terminals of the transmitter circuitry 120 are coupled to the isolation transformer 130. Examples of the transmitter circuitry 120 are illustrated and described in connection with FIGS. 3, 4, 5, and 6, below.

The isolation transformer 130 has a first terminal, a second terminal, a third terminal, a fourth terminal, a fifth terminal, and a sixth terminal. The first and second terminals of the isolation transformer 130 are coupled to the transmitter circuitry 120. The third terminal of the isolation transformer 130 is coupled to the first common terminal, which supplies the first common potential. The fourth and fifth terminals of the isolation transformer 130 are coupled to the receiver circuitry 135. The sixth terminal of the isolation transformer 130 is coupled to a second common terminal (GND2) that may be electrically isolated from the first common terminal, which supplies a second common potential.

The receiver circuitry 135 has a first terminal, a second terminal, a third terminal, and a fourth terminal. The first and second terminals of the receiver circuitry 135 are coupled to the isolation transformer 130. The third terminal of the receiver circuitry 135 is coupled to the second common terminal, which supplies the second common potential. The fourth terminal of the receiver circuitry 135 is structured to be coupled to external circuitry, which receives the digital signal.

The oscillation circuitry 140 is coupled to the programmable circuitry 105, the isolation transformer 130, and the oscillation circuitry 145. Examples of the oscillation circuitry 140 are illustrated and described in connection with FIGS. 3, 4, 5, and 6, below. The oscillation circuitry 145 is coupled to the programmable circuitry 105, the isolation transformer 130, and the oscillation circuitry 140. Examples of the oscillation circuitry 145 are illustrated and described in connection with FIGS. 3, 4, 5, and 6, below.

The inductor 150 has a first terminal and a second terminal. The first terminal of the inductor 150 is coupled to the transmitter circuitry 120. The second terminal of the inductor 150 is coupled to the first common terminal, which supplies the first common potential. In the example of FIG. 1, the inductor 150 is electromagnetically coupled to the inductor 160. The inductor 155 has a first terminal and a second terminal. The first terminal of the inductor 155 is coupled to the transmitter circuitry 120. The second terminal of the inductor 155 is coupled to the first common terminal, which supplies the first common potential. In the example of FIG. 1, the inductor 155 is electromagnetically coupled to the inductor 165. In some examples, the inductors 150, 155 form first inductor circuitry that is electrically coupled to the transmitter circuitry 120.

The inductor 160 has a first terminal and a second terminal. The first terminal of the inductor 160 is coupled to the receiver circuitry 135. The second terminal of the inductor 160 is coupled to the second common terminal, which supplies the second common potential. In the example of FIG. 1, the inductor 160 is electromagnetically coupled to the inductor 150. The inductor 165 has a first terminal and a second terminal. The first terminal of the inductor 165 is coupled to the receiver circuitry 135. The second terminal of the inductor 165 is coupled to the second common terminal, which supplies the second common potential. In the example of FIG. 1, the inductor 165 is electromagnetically coupled to the inductor 155. In some examples, the inductors 160, 165 form second inductor circuitry that is electrically coupled to the receiver circuitry and magnetically coupled to the first inductor circuitry of the inductors 150, 155.

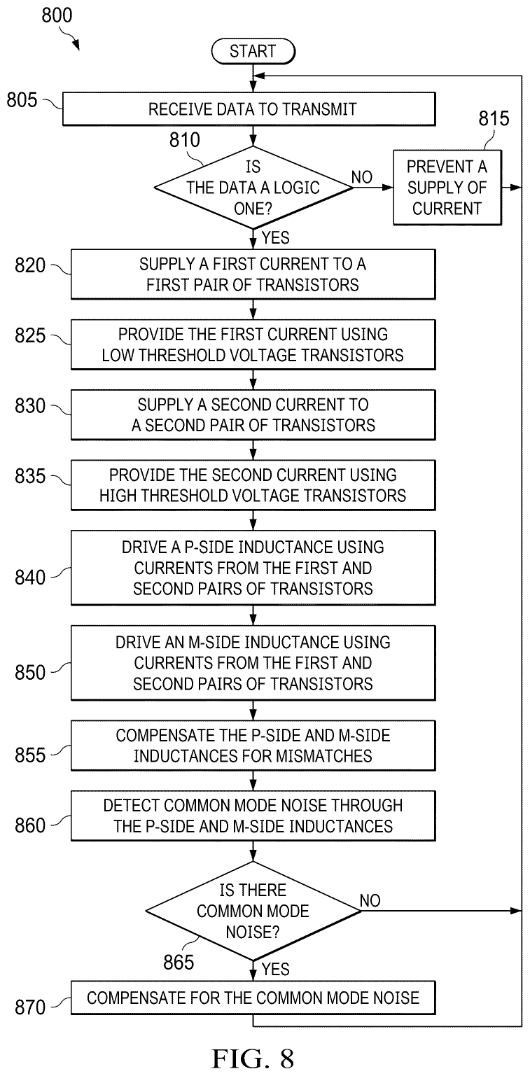

In example operation, the programmable circuitry 105 generates a digital signal for transmission across the isolation transformer 130 to the receiver circuitry 135. In the example of FIG. 1, the transmitter circuitry 120 uses on-off keying to modulate the digital signal onto a sinusoidal carrier signal. The transmitter circuitry 120 generates the sinusoidal signal that carries the digital data across the isolation transformer 130 by controlling the oscillator circuitry 140, 145. The oscillator circuitry 140, 145 generates the sinusoidal signal by regulating a supply of current to LC tank circuitry (illustrated and described in connection with FIGS. 3, 4, 5, and 6, below). In the example of FIG. 1, the oscillator circuitry 140 uses low threshold voltage characteristics and the oscillator circuitry 145 uses high-performance characteristics to regulate currents. Example operations of the oscillator circuitry 140, 145 are described in further detail in connection with FIG. 8, below. Advantageously, using different characteristics of the oscillator circuitry 140, 145 to regulate currents that generate the sinusoidal signal decreases radiated emissions and improves performance.

In such example operations, the inductors 150, 155 induce the modulated sinusoidal signal in the inductors 160, 165 responsive to being magnetically coupled. The receiver circuitry 135 demodulates the modulated sinusoidal signal to generate a digital output signal that represents the digital signal from the programmable circuitry. Advantageously, the programmable circuitry 105 is digitally isolated from noise of external circuitry coupled to the receiver circuitry 135.

In the example of FIG. 1, the receiver circuitry 135 includes circuitry to detect current ripples and generate pulses. In example operation, the receiver circuitry 135 detects current ripples responsive to the current induced in the inducers 160, 165. Also, the receiver circuitry 135 generates a PWM signal using logic levels of the secondary side by generating pulses responsive to the detection of current ripples. In such examples, the receiver circuitry 135 sets the duty cycle of pulses of the PWM signal based on the duration of current ripples in the inductors 160, 165.

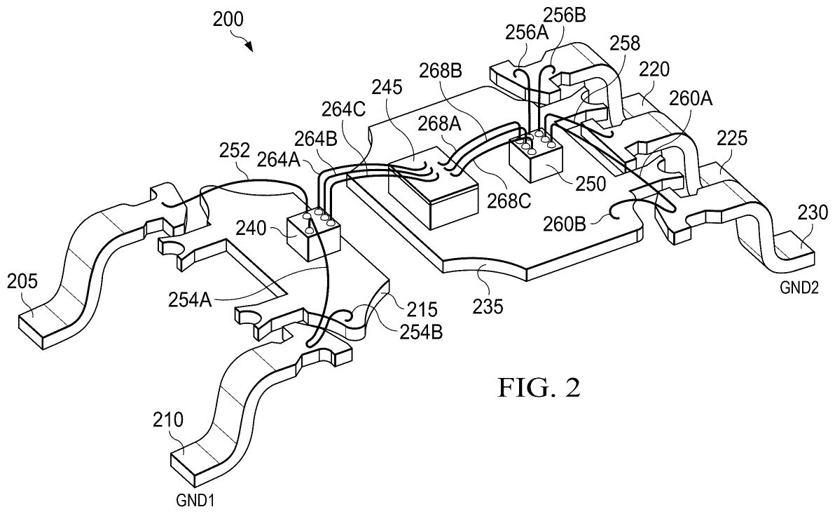

FIG. 2 is an illustration of an example device 200, which implements the isolation system 100 of FIG. 1 in a multi-chip module (MCM). In the example of FIG. 2, the device 200 includes a first lead 205, a second lead 210, a first lead frame 215, a third lead 220, a fourth lead 225, a fifth lead 230, a second lead frame 235, a first die 240, a second die 245, and a third die 250. In the example of FIG. 2, the device 200 implements the communication channel 110 of FIG. 1 using the die 240, 245, 250. Alternatively, the device 200 may include another instance of the die 240, 245, 250 to also implement the communication channel 115. Also, the device 200 may include any number of instances of the die 240, 245, 250 to implement any number of communication channels.

The lead 205 is electrically coupled to the die 240 by an example bond wire 252. In some examples, the lead 205 may be coupled to the programmable circuitry 105 of FIG. 1, which supplies the digital input signal for transmission. The lead 210 is electrically coupled to the die 240 by an example bond wire 254A and the lead frame 215 by another example bond wire 254B. The lead frame 215 is electrically coupled to the lead 210 by the bond wire 254B. The lead frame 215 is mechanically coupled to the die 240. In some examples, the lead frame 215 is mechanically coupled to the die 240 by an adhesive. In the example of FIG. 2, the lead 210 supplies the first common potential to the lead frame 215 responsive to the lead 230 connecting the lead frame 215 to a portion of an external device structured to supply the first common potential. In some examples, the lead 210 may be referred to as a common terminal, which supplies the common potential.

The lead 220 is electrically coupled to the die 250 by example bond wires 256A, 256B. In some examples, the lead 220 may be coupled to external circuitry structured to receive data from the programmable circuitry across the communication channel 110 of FIG. 1. The lead 225 is electrically coupled to the die 250 by an example bond wire 258. In some examples, the lead 225 may be coupled to external circuitry structured to receive data from the programmable circuitry across the communication channel 110. The lead 230 is electrically coupled to the die 250 by an example bond wire 260A and the lead frame 235 by another example bond wire 260B. The lead frame 235 is electrically coupled to the lead 230 by the bond wire 260A. The lead frame 235 is mechanically coupled to the die 245, 250. In some examples, the lead frame 235 is mechanically coupled to the die 245, 250 by an adhesive. In the example of FIG. 2, the lead 230 supplies the second common potential to the lead frame 235 responsive to the lead 230 connecting the lead frame 235 to a portion of a device structured to supply the second common potential. In some examples, the lead 220 may be referred to as a common terminal, which supplies the common potential.

During manufacturing, manufacturers may use an example mold flow process to encapsulate the device 200 in an insulating material to create an isolating system package. When packaged, the insulating material protects the bond wires 252, 254A, 254B, 256A, 256B, 258, 260A, 260B, 264A, 264B, 264C, 268A, 268B, 268C. Alternatively, the insulating material may be illustrated as a package of the device 200.

The die 240 is electrically coupled to the leads 205, 210 by the bond wires 252, 254A and the die 245 by example bond wires 264A, 264B, 264C. The die 240 is mechanically coupled to the lead frame 215. In the example of FIG. 2, the die 240 implements the transmitter circuitry 120 of FIG. 1.

The die 245 is electrically coupled to the die 240 by the bond wires 264A, 264B, 264C and the die 250 by example bond wires 268A, 268B, 268C. The die 245 is mechanically coupled to the lead frame 235. In the example of FIG. 2, the die 245 implements the isolation transformer 130 of FIG. 1.

The die 250 is electrically coupled to the leads 220, 225, 230 by the bond wires 256A, 256B, 258, 260B and the die 245 by the bond wires 268A, 268B, 268C. The die 250 is mechanically coupled to the lead frame 235. In the example of FIG. 2, the die 250 implements the receiver circuitry 135 of FIG. 1.

FIG. 3 is a schematic diagram of the inductors 150, 155 of FIG. 1 and example transmitter circuitry 300, which is an example of the transmitter circuitry 120 of FIG. 1. In the example of FIG. 3, the transmitter circuitry 300 includes first oscillator circuitry 305, second oscillator circuitry 310, first inductor-capacitor (LC) tank circuitry 315, second LC tank circuitry 320, and a first example capacitor 325. The example oscillator circuitry 305 of FIG. 3 includes first example current source circuitry 330, a first example transistor 335, and a second example transistor 340. The example oscillator circuitry 305 of FIG. 3 includes second example current source circuitry 345, a third example transistor 350, and a fourth example transistor 355. The example LC tank circuitry 315 of FIG. 3 includes the inductor 150, a second example capacitor 360, and a first example resistor 365. The example LC tank circuitry 320 of FIG. 3 includes the inductor 155, a third example capacitor 375, and a second example resistor 380. In the example of FIG. 3, the transmitter circuitry 300 has an input terminal coupled to a data terminal (DATA), which supplies a digital input signal. In the example of FIG. 1, the programmable circuitry 105 of FIG. 1 supplies the digital input signal.

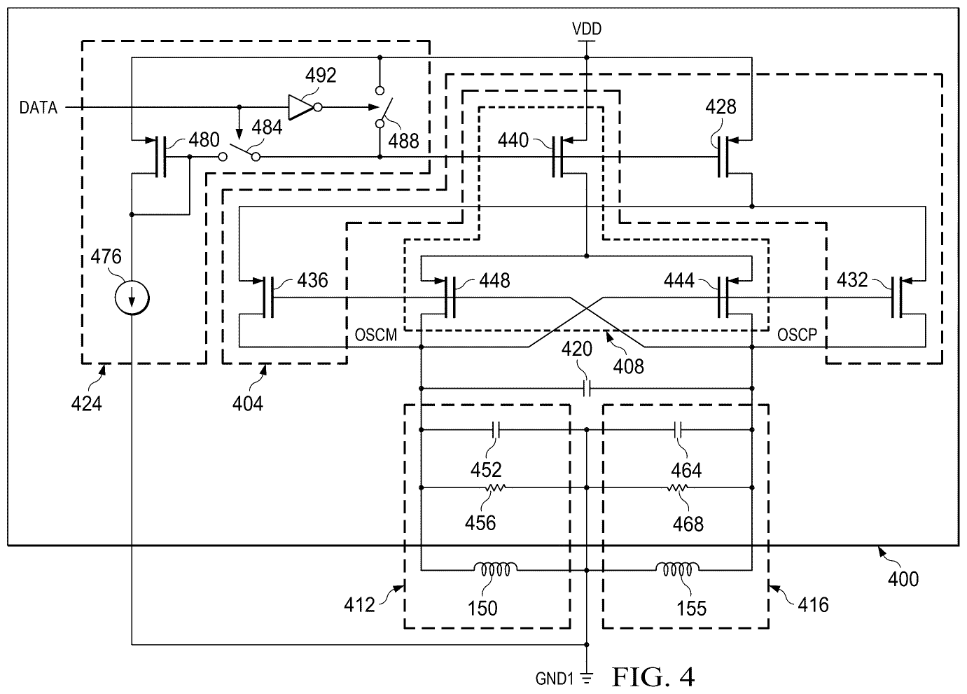

The oscillator circuitry 305 has a first terminal, a second terminal, a third terminal, and a fourth terminal. The first terminal of the oscillator circuitry 305 is coupled to a supply terminal, which supplies a supply voltage (Vdd). The second terminal of the oscillator circuitry 305 is coupled to the data terminal, which supplies the digital input signal. The third terminal of the oscillator circuitry 305 is coupled to the oscillator circuitry 310, the LC tank circuitry 315, and the capacitor 325. The fourth terminal of the oscillator circuitry 305 is coupled to the oscillator circuitry 310, the LC tank circuitry 315, and the capacitor 325. The oscillator circuitry 305 is an example of the oscillator circuitry 140 of FIG. 1. Another example of the oscillator circuitry 305 is illustrated and described in connection with FIG. 4, below.

The oscillator circuitry 310 has a first terminal, a second terminal, a third terminal, and a fourth terminal. The first terminal of the oscillator circuitry 310 is coupled to the supply terminal, which supplies the supply voltage. The second terminal of the oscillator circuitry 310 is coupled to the data terminal, which supplies the digital input signal. The third terminal of the oscillator circuitry 310 is coupled to the oscillator circuitry 305, the LC tank circuitry 315, and the capacitor 325. The fourth terminal of the oscillator circuitry 310 is coupled to the oscillator circuitry 305, the LC tank circuitry 315, and the capacitor 325. The oscillator circuitry 310 is an example of the oscillator circuitry 145 of FIG. 1. Another example of the oscillator circuitry 310 is illustrated and described in connection with FIG. 4, below.

The LC tank circuitry 315 has a first terminal and a second terminal. The first terminal of the LC tank circuitry 315 is coupled to the oscillator circuitry 305, 310 and the capacitor 325. The second terminal of the LC tank circuitry 315 is coupled to a common terminal, which supplies a common potential. In the example of FIG. 3, one or more components of the LC tank circuitry 315 may be separated across one or more dies. For example, the die 240 of FIG. 2 includes the capacitor 360 and the resistor 365 and the die 245 includes the inductor 150. Alternatively, in some examples, the components of the LC tank circuitry 315 are illustrated and described as part of the transmitter circuitry 300. In such examples, one or more of the components of the LC tank circuitry 320 may be on the same or spread across multiple dies.

The LC tank circuitry 320 has a first terminal and a second terminal. The first terminal of the LC tank circuitry 320 is coupled to the oscillator circuitry 305, 310 and the capacitor 325. The second terminal of the LC tank circuitry 320 is coupled to a common terminal, which supplies a common potential. In the example of FIG. 3, one or more components of the LC tank circuitry 320 may be separated across one or more dies. For example, the die 240 includes the capacitor 375 and the resistor 380, and the die 245 includes the inductor 155. Alternatively, in some examples, the components of the LC tank circuitry 320 are illustrated and described as part of the transmitter circuitry 300. In such examples, one or more of the components of the LC tank circuitry 320 may be on the same or spread across multiple dies.

The capacitor 325 has a first terminal and a second terminal. The first terminal of the capacitor 325 is coupled to the oscillator circuitry 305, 310 and the LC tank circuitry 315. The second terminal of the capacitor 325 is coupled to the oscillator circuitry 305, 310 and the LC tank circuitry 320. In some examples, the capacitor 325 is referred to as a differential capacitor that forms a differential filter. In such examples, the capacitor 325 is structured as a low pass filter, which reduces noise from the switching of the transistors 335, 340, 355, 350.

The current source circuitry 330 has a first terminal, a second terminal, and a control terminal. The first terminal of the current source circuitry 330 is coupled to the supply terminal, which supplies the supply voltage. The second terminal of the current source circuitry 330 is coupled to the transistors 335, 340. The control terminal of the current source circuitry 330 is coupled to the data terminal, which supplies the digital input signal.

The transistor 335 has a first terminal, a second terminal, and a control terminal. The first terminal of the transistor 335 is coupled to the current source circuitry 330 and the transistor 340. The second terminal of the transistor 335 is coupled to the oscillator circuitry 310, the LC tank circuitry 320, the capacitor 325, and the transistor 340. The control terminal of the transistor 335 is coupled to the oscillator circuitry 310, the LC tank circuitry 315, the capacitor 325, and the transistor 340. The transistor 340 has a first terminal, a second terminal, and a control terminal. The first terminal of the transistor 340 is coupled to the current source circuitry 330 and the transistor 335. The second terminal of the transistor 340 is coupled to the oscillator circuitry 310, the LC tank circuitry 315, the capacitor 325, and the transistor 335. The control terminal of the transistor 340 is coupled to the oscillator circuitry 310, the LC tank circuitry 320, the capacitor 325, and the transistor 335. In some examples, the transistors 335, 340 may be referred to as a pair of cross-coupled transistors.

The current source circuitry 345 has a first terminal, a second terminal, and a control terminal. The first terminal of the current source circuitry 345 is coupled to the supply terminal, which supplies the supply voltage. The second terminal of the current source circuitry 345 is coupled to the transistors 350, 355. The control terminal of the current source circuitry 345 is coupled to the data terminal, which supplies the digital input signal.

The transistor 350 has a first terminal, a second terminal, and a control terminal. The first terminal of the transistor 350 is coupled to the current source circuitry 345 and the transistor 355. The second terminal of the transistor 350 is coupled to the oscillator circuitry 305, the LC tank circuitry 315, the capacitor 325, and the transistor 355. The control terminal of the transistor 350 is coupled to the oscillator circuitry 305, the LC tank circuitry 320, the capacitor 325, and the transistor 355. The transistor 355 has a first terminal, a second terminal, and a control terminal. The first terminal of the transistor 355 is coupled to the current source circuitry 345 and the transistor 350. The second terminal of the transistor 355 is coupled to the oscillator circuitry 305, the LC tank circuitry 320, the capacitor 325, and the transistor 350. The control terminal of the transistor 355 is coupled to the oscillator circuitry 305, the LC tank circuitry 315, the capacitor 325, and the transistor 350. In some examples, the transistors 350, 355 may be referred to as a pair of cross-coupled transistors.

The capacitor 360 has a first terminal and a second terminal. The first terminal of the capacitor 360 is coupled to the oscillator circuitry 305, 310, the capacitor 325, the resistor 365, and the inductor 150. The second terminal of the capacitor 360 is coupled to the common terminal, which supplies the common potential. The resistor 365 has a first terminal and a second terminal. The first terminal of the resistor 365 is coupled to the oscillator circuitry 305, 310, the capacitors 325, 360, and the inductor 150. The second terminal of the resistor 365 is coupled to the common terminal, which supplies the common potential.

The capacitor 375 has a first terminal and a second terminal. The first terminal of the capacitor 375 is coupled to the oscillator circuitry 305, 310, the capacitor 325, the resistor 380, and the inductor 155. The second terminal of the capacitor 375 is coupled to the common terminal, which supplies the common potential. The resistor 380 has a first terminal and a second terminal. The first terminal of the resistor 380 is coupled to the oscillator circuitry 305, 310, the capacitors 325, 375, and the inductor 155. The second terminal of the resistor 380 is coupled to the common terminal, which supplies the common potential.

In the example of FIG. 3, the transistors 335, 340, 350, 355 are p-channel metal-oxide semiconductor field-effect transistors (MOSFETs). Alternatively, the transistors 335, 340, 350, 355 may be p-channel field-effect transistors (FETs), p-channel insulated-gate bipolar transistors (IGBTs), p-channel junction field effect transistors (JFETs), PNP bipolar junction transistors (BJTs) or, with slight modifications, n-type equivalent devices. In some examples, the transistors 335, 340, 350, 355 may be depletion mode devices, drain-extended devices, enhancement mode devices, natural transistors, or other types of device structure transistors. Furthermore, the transistors 335, 340, 350, 355 may be implemented in/over a silicon substrate (Si), a silicon carbide substrate (SiC), a gallium nitride substrate (GaN) or a gallium arsenide substrate (GaAs).

In example operations, the logic state of the digital input signal controls the current source circuitry 330, 345. When the digital input signal is a logic one, the current source circuitry 330, 345 supplies current to the transistors 335, 340, 350, 355. The LC tank circuitry 315, 320 generates a sinusoidal signal responsive to currents from the transistors 335, 340, 350, 355. The transistors 335, 340, 350, 355 compensate for the LC tank circuitry 315, 320 loss and initializing oscillation. The LC tank circuitry 315, 320 transmit the sinusoidal signal across the isolation transformer 130 of FIG. 1 using the inductors 150, 155. In such example operations, the resistors 365, 380 are structured to reduce mismatch between the inductors 150, 155 by reducing asymmetries of equivalent resistances. The operations of the resistors 365, 380 are described in further detail in connection with FIG. 8, below.

In the example of FIG. 3, the transistors 335, 340 are low threshold voltage transistors, which are manufactured to have a threshold voltage that is less than some other transistors. For example, the transistors 335, 340 have a threshold voltage approximately equal to four-tenths of a volt, and the transistors 350, 355 have a threshold voltage approximately equal to seven-tenths of a volt. Also, the low threshold voltage transistors have a smaller transconductance in comparison to the transistors 350, 355, which reduces the amount of current supplied by the transistors 335, 340. Advantageously, utilizing different transistors having different thresholds allow transistors of at least one of the oscillator circuitry 305, 310 to continue to conduct current at relatively small voltages. Such a continuous conduction minimizes a tail node noise when switching between conduction modes. The operations of the oscillator circuitry 305, 310 are described in further detail in connection with FIG. 8, below.

FIG. 4 is a schematic diagram of the inductors 150, 155 of FIG. 1 and example transmitter circuitry 400, which is another example of the transmitter circuitry 120, 300 of FIGS. 1 and 3. In the example of FIG. 4, the transmitter circuitry 400 includes first oscillator circuitry 404, second oscillator circuitry 408, first LC tank circuitry 412, second LC tank circuitry 416, a first capacitor 420, and bias circuitry 424. The example oscillator circuitry 404 of FIG. 4 includes a first example transistor 428, a second example transistor 432, and a third example transistor 436. The example oscillator circuitry 408 of FIG. 4 includes a fourth example transistor 440, a fifth example transistor 444, and a sixth example transistor 448. The example LC tank circuitry 412 of FIG. 4 includes the inductor 150, a second example capacitor 452, and a first example resistor 456. The example LC tank circuitry 416 of FIG. 4 includes the inductor 155, a third example capacitor 464, and a second example resistor 468. The example bias circuitry 424 of FIG. 4 includes example current source circuitry 476, a seventh example transistor 480, a first example switch 484, a second example switch 488, and an example inverter 492. In the example of FIG. 4, the transmitter circuitry 400 has an input terminal coupled to a data terminal (DATA), which supplies a digital input signal. In the example of FIG. 1, the programmable circuitry 105 of FIG. 1 supplies the digital input signal.

The oscillator circuitry 404 has a first terminal, a second terminal, a third terminal, and a fourth terminal. The first terminal of the oscillator circuitry 404 is coupled to a supply terminal, which supplies a supply voltage. The second terminal of the oscillator circuitry 404 is coupled to the oscillator circuitry 408 and the bias circuitry 424. The third terminal of the oscillator circuitry 404 is coupled to the oscillator circuitry 408, the LC tank circuitry 412, and the capacitor 420. The fourth terminal of the oscillator circuitry 404 is coupled to the oscillator circuitry 408, the LC tank circuitry 416, and the capacitor 420. The oscillator circuitry 404 is an example of the oscillator circuitry 140, 305 of FIGS. 1 and 3.

The oscillator circuitry 408 has a first terminal, a second terminal, a third terminal, and a fourth terminal. The first terminal of the oscillator circuitry 408 is coupled to a supply terminal, which supplies the supply voltage. The second terminal of the oscillator circuitry 408 is coupled to the oscillator circuitry 404 and the bias circuitry 424. The third terminal of the oscillator circuitry 408 is coupled to the oscillator circuitry 404, the LC tank circuitry 412, and the capacitor 420. The fourth terminal of the oscillator circuitry 408 is coupled to the oscillator circuitry 404, the LC tank circuitry 416, and the capacitor 420. The oscillator circuitry 408 is an example of the oscillator circuitry 145, 310 of FIGS. 1 and 3.

The LC tank circuitry 412 has a first terminal and a second terminal. The first terminal of the LC tank circuitry 412 is coupled to the oscillator circuitry 404, 408 and the capacitor 420. The second terminal of the LC tank circuitry 412 is coupled to a common terminal, which supplies the common potential. In the example of FIG. 4, the LC tank circuitry 412 is described and illustrated as a part of the transmitter circuitry 400. However, one or more components of the LC tank circuitry 412 may be separated across one or more dies. For example, the die 240 of FIG. 2 includes the capacitor 452 and the resistor 456 and the die 245 of FIG. 2 includes the inductor 150. The LC tank circuitry 412 is another example of the LC tank circuitry 315 of FIG. 3.

The LC tank circuitry 416 has a first terminal and a second terminal. The first terminal of the LC tank circuitry 416 is coupled to the oscillator circuitry 404, 408 and the capacitor 420. The second terminal of the LC tank circuitry 416 is coupled to a common terminal, which supplies the common potential. In the example of FIG. 4, the LC tank circuitry 416 is described and illustrated as a part of the transmitter circuitry 400. However, one or more components of the LC tank circuitry 416 may be separated across one or more dies. For example, the die 240 includes the capacitor 464 and the resistor 468 and the die 245 includes the inductor 155. The LC tank circuitry 416 is another example of the LC tank circuitry 320 of FIG. 3.

The capacitor 420 has a first terminal and a second terminal. The first terminal of the capacitor 420 is coupled to the oscillator circuitry 404, 408 and the LC tank circuitry 412. The second terminal of the capacitor 420 is coupled to the oscillator circuitry 404, 408 and the LC tank circuitry 416. In some examples, the capacitor 420 is referred to as a differential capacitor. The capacitor 420 is another example of the capacitor 325 of FIG. 3.

The bias circuitry 424 has a first terminal, a second terminal, a third terminal, and a fourth terminal. The first terminal of the bias circuitry 424 is coupled to the supply terminal, which supplies the supply voltage. The second terminal of the bias circuitry 424 is coupled to the data terminal, which supplies the digital input signal. The third terminal of the bias circuitry 424 is coupled to the oscillator circuitry 404, 408. The fourth terminal of the bias circuitry 424 is coupled to the common terminal, which supplies the common potential.

The transistor 428 has a first terminal, a second terminal, and a control terminal. The first terminal of the transistor 428 is coupled to the supply terminal, which supplies the supply voltage. The second terminal of the transistor 428 is coupled to the transistors 432, 436. The control terminal of the transistor 428 is coupled to the oscillator circuitry 408 and the bias circuitry 424. In the example of FIG. 4, the transistor 428 is structured as current source circuitry, which supplies a current based on the bias circuitry 424.

The transistor 432 has a first terminal, a second terminal, and a control terminal. The first terminal of the transistor 432 is coupled to the transistors 428, 436. The second terminal of the transistor 432 is coupled to the oscillator circuitry 408, the LC tank circuitry 416, the capacitor 420, and the transistor 436. The control terminal of the transistor 432 is coupled to the oscillator circuitry 408, the LC tank circuitry 412, the capacitor 420, and the transistor 436.

The transistor 436 has a first terminal, a second terminal, and a control terminal. The first terminal of the transistor 436 is coupled to the transistors 428, 432. The second terminal of the transistor 436 is coupled to the oscillator circuitry 408, the LC tank circuitry 412, the capacitor 420, and the transistor 432. The control terminal of the transistor 436 is coupled to the oscillator circuitry 408, the LC tank circuitry 416, the capacitor 420, and the transistor 432.

The transistor 440 has a first terminal, a second terminal, and a control terminal. The first terminal of the transistor 440 is coupled to the supply terminal, which supplies the supply voltage. The second terminal of the transistor 440 is coupled to the transistors 444, 448. The control terminal of the transistor 440 is coupled to the oscillator circuitry 404 and the bias circuitry 424. In the example of FIG. 4, the transistor 440 is structured as current source circuitry, which supplies a current based on the bias circuitry 424.

The transistor 444 has a first terminal, a second terminal, and a control terminal. The first terminal of the transistor 444 is coupled to the transistors 440, 448. The second terminal of the transistor 444 is coupled to the oscillator circuitry 404, the LC tank circuitry 416, the capacitor 420, and the transistor 448. The control terminal of the transistor 444 is coupled to the oscillator circuitry 404, the LC tank circuitry 412, the capacitor 420, and the transistor 448.

The transistor 448 has a first terminal, a second terminal, and a control terminal. The first terminal of the transistor 448 is coupled to the transistors 440, 444. The second terminal of the transistor 448 is coupled to the oscillator circuitry 404, the LC tank circuitry 412, the capacitor 420, and the transistor 444. The control terminal of the transistor 448 is coupled to the oscillator circuitry 404, the LC tank circuitry 416, the capacitor 420, and the transistor 444.

The capacitor 452 has a first terminal and a second terminal. The first terminal of the capacitor 452 is coupled to the oscillator circuitry 404, 408, the capacitor 420, the resistor 456, and the inductor 150. The second terminal of the capacitor 452 is coupled to the common terminal, which supplies the common potential. The capacitor 452 is another example of the capacitor 360 of FIG. 3. The resistor 456 has a first terminal and a second terminal. The first terminal of the resistor 456 is coupled to the oscillator circuitry 404, 408, the capacitors 420, 452, and the inductor 150. The second terminal of the resistor 456 is coupled to the common terminal, which supplies the common potential. The resistor 456 is another example of the resistor 365 of FIG. 3.

The capacitor 464 has a first terminal and a second terminal. The first terminal of the capacitor 464 is coupled to the oscillator circuitry 404, 408, the capacitor 420, the resistor 468, and the inductor 155. The second terminal of the capacitor 464 is coupled to the common terminal, which supplies the common potential. The capacitor 464 is another example of the capacitor 375 of FIG. 3. The resistor 468 has a first terminal and a second terminal. The first terminal of the resistor 468 is coupled to the oscillator circuitry 404, 408, the capacitors 420, 464, and the inductor 155. The second terminal of the resistor 468 is coupled to the common terminal, which supplies the common potential. The resistor 468 is another example of the resistor 380 of FIG. 3.

The current source circuitry 476 has a first terminal and a second terminal. The first terminal of the current source circuitry 476 is coupled to the transistor 480 and the switch 484. The second terminal of the current source circuitry 476 is coupled to the common terminal, which supplies the common potential.

The transistor 480 has a first terminal, a second terminal, and a control terminal. The first terminal of the transistor 480 is coupled to the supply terminal, which supplies the supply voltage. The second and control terminals of the transistor 480 are coupled to the current source circuitry 476 and the switch 484.

The switch 484 has a first terminal, a second terminal, and a control terminal. The first terminal of the switch 484 is coupled to the current source circuitry 476 and the transistor 480. The second terminal of the switch 484 is coupled to the oscillator circuitry 404, 408 and the switch 488. The control terminal of the switch 484 is coupled to the data terminal, which supplies the digital input signal. In some examples, the switch 484 may be implemented using a transistor. Alternatively, the switch 484 may be implemented using other switch circuitry.

The switch 488 has a first terminal, a second terminal, and a control terminal. The first terminal of the switch 488 is coupled to the supply terminal, which supplies the supply voltage. The second terminal of the switch 488 is coupled to the oscillator circuitry 404, 408 and the switch 484. The control terminal of the switch 488 is coupled to the inverter 492. In some examples, the switch 488 may be implemented using a transistor. Alternatively, the switch 488 may be implemented using other switch circuitry.

The inverter 492 has a first terminal and a second terminal. The first terminal of the inverter 492 is coupled to the data terminal, which supplies the digital input signal. The second terminal of the inverter 492 is coupled to the switch 488.

In the example of FIG. 4, the transistors 428, 432, 436, 440, 444, 448, 480 are p-channel MOSFETs. Alternatively, the transistors 428, 432, 436, 440, 444, 448, 480 may be p-channel FETs, p-channel IGBTs, p-channel JFETs, PNP BJTs or, with slight modifications, n-type equivalent devices. In some examples, the transistors 428, 432, 436, 440, 444, 448, 480 may be depletion mode devices, drain-extended devices, enhancement mode devices, natural transistors, or other type of device structure transistors. Furthermore, the transistors 428, 432, 436, 440, 444, 448, 480 may be implemented in/over a silicon substrate (Si), a silicon carbide substrate (SiC), a gallium nitride substrate (GaN) or a gallium arsenide substrate (GaAs).

In example operations, the logic state of the digital input signal controls the switches 484, 488, which control the transistors 428, 440. When the digital input signal is a logic one, the switch 484 is closed and the switch 488 is opened. In such operations, the current source circuitry 476 pulls the control terminals of the transistors 428, 440 by the bias voltage, which is set by the transistor 480. The transistors 428, 440 supply current to the transistors 432, 436, 444, 448 responsive to the current source circuitry 476 pulling the control terminals low. The operations of the oscillator circuitry 404, 408 and the LC tank circuitry 412, 416 are similar to in FIG. 3 and are described in further detail in connection with FIG. 8, below.

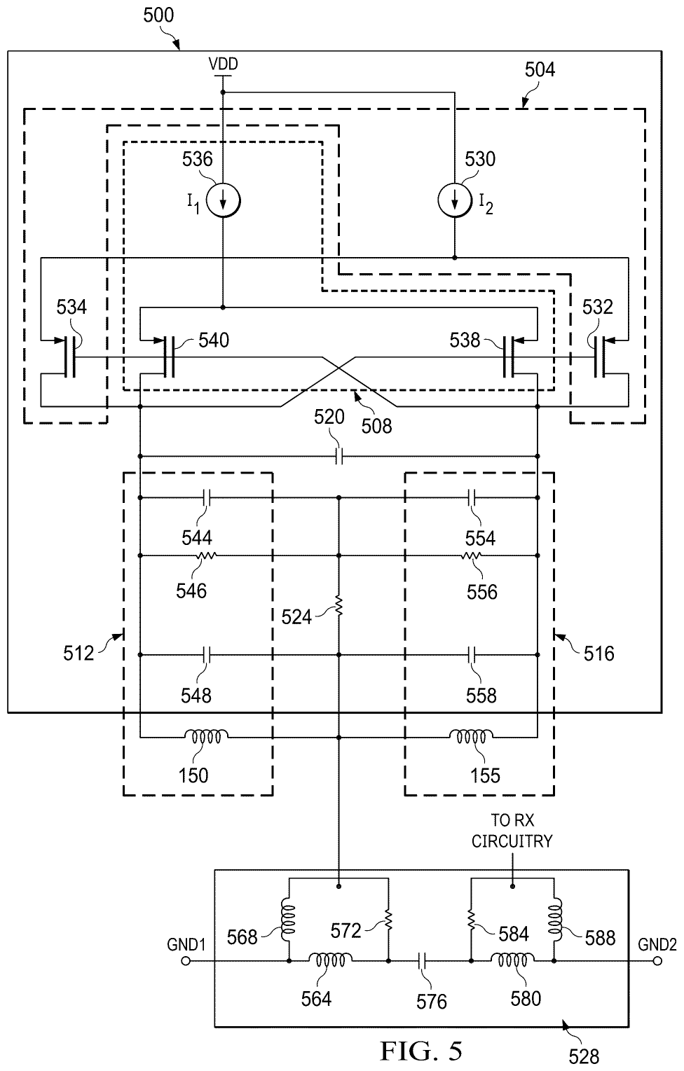

FIG. 5 is a schematic diagram of the inductors 150, 155 of FIG. 1 and example transmitter circuitry 500, which is another example of the transmitter circuitry 120, 300, 400 of FIGS. 1, 3, and 4. In the example of FIG. 5, the transmitter circuitry 500 includes first oscillator circuitry 504, second oscillator circuitry 508, first LC tank circuitry 512, second LC tank circuitry 516, a first capacitor 520, a first resistor 524, and ground path circuitry 528. The example oscillator circuitry 504 of FIG. 5 includes first example current source circuitry 530, a first example transistor 532, and a second example transistor 534. The example oscillator circuitry 508 of FIG. 5 includes second example current source circuitry 536, a third example transistor 538, and a fourth example transistor 540. The example LC tank circuitry 512 of FIG. 5 includes the inductor 150, a second example capacitor 544, a second example resistor 546, and a third example capacitor 548. The example LC tank circuitry 516 of FIG. 5 includes the inductor 155, a fourth example capacitor 554, a third example resistor 556, and a fifth example capacitor 558. The example ground path circuitry 528 of FIG. 5 includes a third example inductor 564, a fourth example inductor 568, a fourth example resistor 572, a sixth example capacitor 576, a fifth example inductor 580, a fifth example resistor 584, and a sixth example inductor 588. In the example of FIG. 5, the transmitter circuitry 500 has an input terminal coupled to a data terminal (DATA), which supplies a digital input signal. In the example of FIG. 1, the programmable circuitry 105 of FIG. 1 supplies the digital input signal.

The oscillator circuitry 504 has a first terminal, a second terminal, a third terminal, and a fourth terminal. The first terminal of the oscillator circuitry 504 is coupled to a supply terminal, which supplies a supply voltage. The second terminal of the oscillator circuitry 504 is coupled to the data terminal, which supplies the digital input signal. The third terminal of the oscillator circuitry 504 is coupled to the oscillator circuitry 508, the LC tank circuitry 512, and the capacitor 520. The fourth terminal of the oscillator circuitry 504 is coupled to the oscillator circuitry 508, the LC tank circuitry 516, and the capacitor 520. The oscillator circuitry 504 is another example of the oscillator circuitry 140, 305, 404 of FIGS. 1, 3, and 4.

The oscillator circuitry 508 has a first terminal, a second terminal, a third terminal, and a fourth terminal. The first terminal of the oscillator circuitry 508 is coupled to the supply terminal, which supplies the supply voltage. The second terminal of the oscillator circuitry 508 is coupled to the data terminal, which supplies the digital input signal. The third terminal of the oscillator circuitry 508 is coupled to the oscillator circuitry 504, the LC tank circuitry 512, and the capacitor 520. The fourth terminal of the oscillator circuitry 508 is coupled to the oscillator circuitry 504, the LC tank circuitry 516, and the capacitor 520. The oscillator circuitry 508 is another example of the oscillator circuitry 145, 310, 408 of FIGS. 1, 3, and 4.

The LC tank circuitry 512 has a first terminal, a second terminal, and a third terminal. The first terminal of the LC tank circuitry 512 is coupled to the oscillator circuitry 504, 508 and the capacitor 520. The second terminal of the LC tank circuitry 512 is coupled to the LC tank circuitry 516 and the resistor 524. The third terminal of the LC tank circuitry 512 is coupled to the LC tank circuitry 516, the resistor 524, and the ground path circuitry 528.

The LC tank circuitry 516 has a first terminal, a second terminal, and a third terminal. The first terminal of the LC tank circuitry 516 is coupled to the oscillator circuitry 504, 508 and the capacitor 520. The second terminal of the LC tank circuitry 516 is coupled to the LC tank circuitry 512 and the resistor 524. The third terminal of the LC tank circuitry 516 is coupled to the LC tank circuitry 512 and the ground path circuitry 528.

The capacitor 520 has a first terminal and a second terminal. The first terminal of the capacitor 520 is coupled to the oscillator circuitry 504, 508 and the LC tank circuitry 512. The second terminal of the capacitor 520 is coupled to the oscillator circuitry 504, 508 and the LC tank circuitry 516. In some examples, the capacitor 520 is referred to as a differential capacitor. The capacitor 520 is another example of the capacitors 325, 420 of FIGS. 3 and 4.

The resistor 524 has a first terminal and a second terminal. The first terminal of the resistor 524 is coupled to the LC tank circuitry 512, 516. The second terminal of the resistor 524 is coupled to the LC tank circuitry 512, 516 and the ground path circuitry 528, which supplies the common potential. In some examples, the resistor 524 is referred to as a blocking resistor or an isolation resistor. In the example of FIG. 5, the resistor 524 is structured to isolate portions of the LC tank circuitry 512, 516 from non-ideal currents from the common potential. For example, when the capacitors 544, 554 and the resistors 546, 556 are in the die 240 of FIG. 2 and the inductors 150, 155 are in the die 245, the resistor 524 reduces an impact of currents from the common terminal from disturbing operations of components of the die 240. The non-ideal ground currents are described in further detail in connection with the ground path circuitry 528 below.

The ground path circuitry 528 has a first terminal, a second terminal, a third terminal, and a fourth terminal. The first terminal of the ground path circuitry 528 is coupled to a first common terminal, which supplies a first common potential. The second terminal of the ground path circuitry 528 is coupled to the LC tank circuitry 512, 516 and the resistor 524. The third terminal of the ground path circuitry 528 is coupled to a second common terminal, which supplies a second common potential. The fourth terminal of the ground path circuitry 528 is structured to be coupled to the receiver circuitry 135 of FIG. 1.

In one example, the LC tank circuitry 512, 516 and the resistor 524 are directly coupled to the first common terminal, which supplies the first common potential. However, implementing the transmitter circuitry 500 results in an indirect path to the second common terminal, which supplied the second common potential. For example, when the lead 210 of FIG. 2 is coupled to the first common terminal, components of the die 240 of FIG. 2 are coupled to the first common terminal by the lead 210 and the bond wire 254A of FIG. 2. Also, the lead 210 is coupled to the lead frame 215 of FIG. 2 by the bond wire 254B of FIG. 2, which adds an additional current path to/from the first common terminal. In the example of FIG. 5, the ground path circuitry 528 is an illustrative representation of equivalent components of implementing the transmitter circuitry 500 using the device 200 of FIG. 2. For example, the components of the ground path circuitry 528 form equivalent circuitry that may supply current from first or second common potentials to the transmitter circuitry 500.

The current source circuitry 530 has a first terminal, a second terminal, and a control terminal. The first terminal of the current source circuitry 530 is coupled to the supply terminal, which supplies the supply voltage. The second terminal of the current source circuitry 530 is coupled to the transistors 532, 534. The control terminal of the current source circuitry 530 is coupled to the data terminal, which supplies the data input signal.

The transistor 532 has a first terminal, a second terminal, and a control terminal. The first terminal of the transistor 532 is coupled to the current source circuitry 530 and the transistor 534. The second terminal of the transistor 532 is coupled to the oscillator circuitry 508, the LC tank circuitry 516, the capacitor 520, and the transistor 534. The control terminal of the transistor 532 is coupled to the oscillator circuitry 508, the LC tank circuitry 512, the capacitor 520, and the transistor 534.

The transistor 534 has a first terminal, a second terminal, and a control terminal. The first terminal of the transistor 534 is coupled to the current source circuitry 530 and the transistor 532. The second terminal of the transistor 534 is coupled to the oscillator circuitry 508, the LC tank circuitry 512, the capacitor 520, and the transistor 532. The control terminal of the transistor 534 is coupled to the oscillator circuitry 508, the LC tank circuitry 516, the capacitor 520, and the transistor 532.

The current source circuitry 536 has a first terminal, a second terminal, and a control terminal. The first terminal of the current source circuitry 536 is coupled to the supply terminal, which supplies the supply voltage. The second terminal of the current source circuitry 536 is coupled to the transistors 538, 540. The control terminal of the current source circuitry 536 is coupled to the data terminal, which supplies the digital input signal.

The transistor 538 has a first terminal, a second terminal, and a control terminal. The first terminal of the transistor 538 is coupled to the current source circuitry 536 and the transistor 540. The second terminal of the transistor 538 is coupled to the oscillator circuitry 504, the LC tank circuitry 516, the capacitor 520, and the transistor 540. The control terminal of the transistor 538 is coupled to the oscillator circuitry 504, the LC tank circuitry 512, the capacitor 520, and the transistor 540.

The transistor 540 has a first terminal, a second terminal, and a control terminal. The first terminal of the transistor 540 is coupled to the current source circuitry 536 and the transistor 538. The second terminal of the transistor 540 is coupled to the oscillator circuitry 504, the LC tank circuitry 512, the capacitor 520, and the transistor 538. The control terminal of the transistor 540 is coupled to the oscillator circuitry 504, the LC tank circuitry 516, the capacitor 520, and the transistor 538.

The capacitor 544 has a first terminal and a second terminal. The first terminal of the capacitor 544 is coupled to the oscillator circuitry 504, 508, the capacitors 520, 548, the resistor 546, and the inductor 150. The second terminal of the capacitor 544 is coupled to the LC tank circuitry 516 and the resistors 524, 546. The resistor 546 has a first terminal and a second terminal. The first terminal of the resistor 546 is coupled to the oscillator circuitry 504, 508, the capacitors 520, 544, 548, and the inductor 150. The second terminal of the resistor 546 is coupled to the LC tank circuitry 516, the resistor 524, and the capacitor 544.

The capacitor 548 has a first terminal and a second terminal. The first terminal of the capacitor 548 is coupled to the oscillator circuitry 504, 508, the capacitors 520, 544, the resistor 546, and the inductor 150. The second terminal of the capacitor 548 is coupled to the LC tank circuitry 516, the ground path circuitry 528, and the inductor 150. In the example of FIG. 5, the capacitor 548 is an example of an equivalent capacitance formed between bond wires that couple the inductor 150 from one die to another. For example, when the inductor 150 is in the die 245 and the transmitter circuitry 500 is in the die 240, the capacitor 548 represents a capacitance formed between the bond wires 264A, 264B of FIG. 2. In some examples, the capacitor 548 may not be illustrated or described as a parasitic capacitor.

The capacitor 554 has a first terminal and a second terminal. The first terminal of the capacitor 554 is coupled to the oscillator circuitry 504, 508, the capacitors 520, 558, the resistor 556, and the inductor 155. The second terminal of the capacitor 554 is coupled to the LC tank circuitry 512 and the resistors 524, 556. The resistor 556 has a first terminal and a second terminal. The first terminal of the resistor 556 is coupled to the oscillator circuitry 504, 508, the capacitors 520, 554, 558, and the inductor 155. The second terminal of the resistor 556 is coupled to the LC tank circuitry 512, the resistor 524, and the capacitor 554.

The capacitor 558 has a first terminal and a second terminal. The first terminal of the capacitor 558 is coupled to the oscillator circuitry 504, 508, the capacitors 520, 554, the resistor 556, and the inductor 155. The second terminal of the capacitor 558 is coupled to the LC tank circuitry 512, the ground path circuitry 528, and the inductor 155. In the example of FIG. 5, the capacitor 558 is an example of an equivalent capacitance formed between bond wires that couple the inductor 155 from one die to another. For example, when the inductor 155 is in the die 245 and the transmitter circuitry 500 is in the die 240, the capacitor 558 represents a capacitance formed between the bond wires 264B, 264C of FIG. 2. In some examples, the capacitor 558 may not be illustrated or described as a parasitic capacitor.

The inductor 564 has a first terminal and a second terminal. The first terminal of the inductor 564 is coupled to the first common terminal, which supplies the first common potential. The second terminal of the inductor 564 is coupled to the resistor 572 and the capacitor 576. In the example of FIG. 5, the inductor 564 is an example of a parasitic inductance formed by a bond wire that couples the lead that supplies the first common potential to the lead frame that supports the transmitter circuitry 500. For example, when the transmitter circuitry 500 is in the die 240, which is on the lead frame 215 of FIG. 2, and the lead 210 is coupled to the first common terminal, the inductor 564 represents an inductance of the bond wire 254B of FIG. 2. In some examples, the inductor 564 may not be illustrated or described as a parasitic inductance.

The inductor 568 has a first terminal and a second terminal. The first terminal of the inductor 568 is coupled to the LC tank circuitry 512, 516 and the resistors 524, 572. The second terminal of the inductor 568 is coupled to the first common terminal, which supplies the first common potential. In the example of FIG. 5, the inductor 568 is an example of a parasitic inductance formed by a bond wire that couples a die containing the transmitter circuitry 500 to the first common terminal. For example, when the transmitter circuitry 500 is in the die 240 and the lead 210 of FIG. 2 is coupled to the first common terminal, the inductor 568 represents an inductance of the bond wire 254A of FIG. 2. In some examples, the inductor 568 may not be illustrated or described as a parasitic inductance.

The resistor 572 has a first terminal and a second terminal. The first terminal of the resistor 572 is coupled to the LC tank circuitry 512, 516, the resistor 524, and the inductor 568. The second terminal of the resistor 572 is coupled to the inductor 564 and the capacitor 576. In the example of FIG. 5, the resistor 572 is an example of an equivalent resistance formed by a die attach pad, which is between the lead frame that supports the transmitter circuitry 500 and the die that includes the transmitter circuitry 500. For example, when the transmitter circuitry 500 is in the die 240, which is on the lead frame 215 of FIG. 2, the resistor 572 represents a resistance of the physical connection of the lead frame 215 to the die 240. In some examples, the resistor 572 may not be illustrated or described as a parasitic resistance.

The capacitor 576 has a first terminal and a second terminal. The first terminal of the capacitor 576 is coupled to the inductor 564 and the resistor 572. The second terminal of the capacitor 576 is coupled to the inductor 580 and the resistor 584. In the example of FIG. 5, the capacitor 576 is an example of a parasitic capacitance formed between a first lead frame that supports the transmitter circuitry 500 and a second lead frame that supports the receiver circuitry 135. For example, when the transmitter circuitry 500 is in the die 240, which is on the lead frame 215, and the receiver circuitry 135 is in the die 250 of FIG. 2, which is on the lead frame 235 of FIG. 2, the capacitor 576 represents a capacitance between the lead frames 215, 235. In some examples, the capacitor 576 may not be illustrated or described as a parasitic capacitance.

The inductor 580 has a first terminal and a second terminal. has a first terminal and a second terminal. The first terminal of the inductor 580 is coupled to the second common terminal, which supplies the second common potential. The second terminal of the inductor 580 is coupled to the capacitor 576 and the resistor 584. In the example of FIG. 5, the inductor 580 is an example of a parasitic inductance formed by a bond wire that couples a lead that supplies the second common potential to a lead frame that supports the receiver circuitry 135. For example, when the receiver circuitry 135 is in the die 250, which is on the lead frame 235, and the lead 230 of FIG. 2 is coupled to the second common terminal, the inductor 580 represents an inductance of the bond wire 260A of FIG. 2. In some examples, the inductor 580 may not be illustrated or described as a parasitic inductance.

The resistor 584 has a first terminal and a second terminal. The first terminal of the resistor 584 is coupled to the receiver circuitry 135 and the inductor 588. The second terminal of the resistor 584 is coupled to the capacitor 576 and the inductor 580. In the example of FIG. 5, the resistor 584 is an example of an equivalent resistance formed by a die attach pad, which is between the lead frame that supports the receiver circuitry 135 and the die that includes the receiver circuitry 135. For example, when the receiver circuitry 135 is in the die 250, which is on the lead frame 235, the resistor 584 represents a resistance of the physical connection of the lead frame 235 to the die 250. In some examples, the resistor 584 may not be illustrated or described as a parasitic resistance.

The inductor 588 has a first terminal and a second terminal. The first terminal of the inductor 588 is coupled to the receiver circuitry 135 and the resistor 584. The second terminal of the inductor 588 is coupled to the second common terminal, which supplies the second common potential. In the example of FIG. 5, the inductor 588 is an example of an equivalent inductance formed by a bond wire that couples a die containing the receiver circuitry 135 to a lead the supplies the second common potential. For example, when the receiver circuitry 135 is in the die 250 and the lead 230 is coupled to the second common terminal, the inductor 588 represents an inductance of the bond wire 260B of FIG. 2. In some examples, the inductor 588 may not be illustrated or described as a parasitic inductance.

In the example of FIG. 5, the transistors 532, 534, 538, 540 are p-channel MOSFETs. Alternatively, the transistors 532, 534, 538, 540 may be p-channel FETs, p-channel IGBTs, p-channel JFETs, PNP BJTs or, with slight modifications, n-type equivalent devices. In some examples, the transistors 532, 534, 538, 540 may be depletion mode devices, drain-extended devices, enhancement mode devices, natural transistors, or other types of device structure transistors. Furthermore, the transistors 532, 534, 538, 540 may be implemented in/over a silicon substrate (Si), a silicon carbide substrate (SiC), a gallium nitride substrate (GaN) or a gallium arsenide substrate (GaAs).

In example operation, non-ideal currents of the common potential may be injected into the transmitter circuitry 500 by one of two possible current paths. A first current path is from the first common terminal across the inductor 568 and into the resistor 524. A second current path is from the second common potential, across the capacitor 576 and through the resistor 572. In either case, the non-ideal currents have to traverse the resistor 524 to disturb the operations of the LC tank circuitry 512, 516. Advantageously, the resistor 524 blocks the non-ideal currents by isolating the capacitors 544, 554 and the resistors 546, 556 from the current paths of the ground path circuitry 528, which improves radiated immunity. The operations of the oscillator circuitry 504, 508 and the LC tank circuitry 512, 516 are similar to in FIGS. 3 and 4 and are described in further detail in connection with FIG. 8, below.

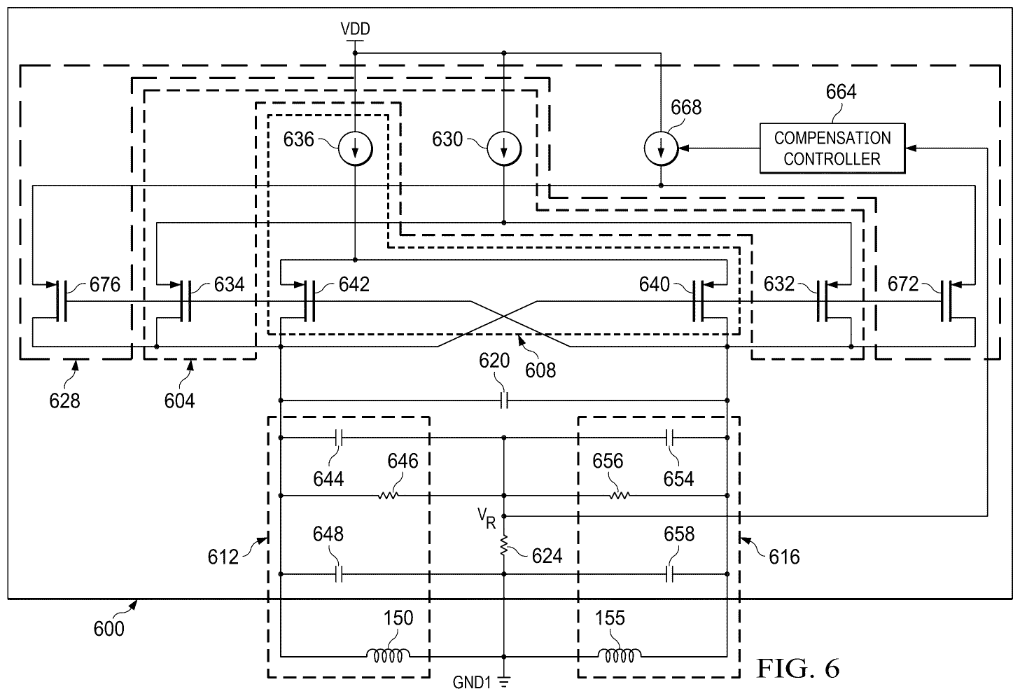

FIG. 6 is a schematic diagram of the inductors 150, 155 of FIG. 1 and example transmitter circuitry 600, which is yet another example of the transmitter circuitry 120, 300, 400, 500 of FIGS. 1, 3, 4, and 5. In the example of FIG. 6, the transmitter circuitry 600 includes first oscillator circuitry 604, second oscillator circuitry 608, first example LC tank circuitry 612, second LC tank circuitry 616, a first example capacitor 620, a first example resistor 624, and example compensation circuitry 628. The example oscillator circuitry 604 of FIG. 6 includes first example current source circuitry 630, a first example transistor 632, and a second example transistor 634. The example oscillator circuitry 608 of FIG. 6 includes second example current source circuitry 636, a third example transistor 640, and a fourth example transistor 642. The example LC tank circuitry 612 of FIG. 6 includes the inductor 150, a second example capacitor 644, a second example resistor 646, and a third example capacitor 648. The example LC tank circuitry 616 of FIG. 6 includes the inductor 155, a fourth example capacitor 654, a third example resistor 656, and a fifth example capacitor 658. The example compensation circuitry 628 of FIG. 6 includes example compensation controller circuitry 664, third example current source circuitry 668, a fifth example transistor 672, and a sixth example transistor 676. In the example of FIG. 6, the transmitter circuitry 600 has an input terminal coupled to a data terminal (DATA), which supplies a digital input signal. In the example of FIG. 1, the programmable circuitry 105 of FIG. 1 supplies the digital input signal.

The oscillator circuitry 604 has a first terminal, a second terminal, a third terminal, and a fourth terminal. The first terminal of the oscillator circuitry 604 is coupled to a supply terminal, which supplies a supply voltage. The second terminal of the oscillator circuitry 604 is coupled to the data terminal, which supplies the digital input signal. The third terminal of the oscillator circuitry 604 is coupled to the oscillator circuitry 608, the LC tank circuitry 612, the capacitor 620, and the compensation circuitry 628. The fourth terminal of the oscillator circuitry 604 is coupled to the oscillator circuitry 608, the LC tank circuitry 616, the capacitor 620, and the compensation circuitry 628. The oscillator circuitry 604 is another example of the oscillator circuitry 140, 305, 404, 504 of FIGS. 1, 3, 4, and 5.

The oscillator circuitry 608 has a first terminal, a second terminal, a third terminal, and a fourth terminal. The first terminal of the oscillator circuitry 608 is coupled to the supply terminal, which supplies the supply voltage. The second terminal of the oscillator circuitry 608 is coupled to the data terminal, which supplies the digital input signal. The third terminal of the oscillator circuitry 608 is coupled to the oscillator circuitry 604, the LC tank circuitry 612, the capacitor 620, and the compensation circuitry 628. The fourth terminal of the oscillator circuitry 608 is coupled to the oscillator circuitry 604, the LC tank circuitry 616, the capacitor 620, and the compensation circuitry 628. The oscillator circuitry 608 is another example of the oscillator circuitry 145, 310, 408, 508 of FIGS. 1, 3, 4, and 5.

The LC tank circuitry 612 has a first terminal, a second terminal, and a third terminal. The first terminal of the LC tank circuitry 612 is coupled to the oscillator circuitry 604, 608 the capacitor 620, and the compensation circuitry 628. The second terminal of the LC tank circuitry 612 is coupled to the LC tank circuitry 616 and the resistor 624. The third terminal of the LC tank circuitry 612 is coupled to the common terminal, which supplies the common potential. The LC tank circuitry 612 is another example of the LC tank circuitry 512 of FIG. 5.

The LC tank circuitry 616 has a first terminal, a second terminal, and a third terminal. The first terminal of the LC tank circuitry 616 is coupled to the oscillator circuitry 604, 608, the capacitor 620, and the compensation circuitry 628. The second terminal of the LC tank circuitry 616 is coupled to the LC tank circuitry 612 and the resistor 624. The third terminal of the LC tank circuitry 616 is coupled to the common terminal, which supplies the common potential. The LC tank circuitry 616 is another example of the LC tank circuitry 516 of FIG. 5.

The capacitor 620 has a first terminal and a second terminal. The first terminal of the capacitor 620 is coupled to the oscillator circuitry 604, 608, the LC tank circuitry 612, and the compensation circuitry 628. The second terminal of the capacitor 620 is coupled to the oscillator circuitry 604, 608, the LC tank circuitry 616, and the compensation circuitry 628. In some examples, the capacitor 620 is referred to as a differential capacitor. The capacitor 620 is another example of the capacitors 325, 420, 520 of FIGS. 3, 4, and 5.

The resistor 624 has a first terminal and a second terminal. The first terminal of the resistor 624 is coupled to the LC tank circuitry 612, 616 and the compensation circuitry 628. The second terminal of the resistor 624 is coupled to the common terminal, which supplies the common potential. In some examples, the resistor 624 is referred to as a blocking resistor or an isolation resistor. The resistor 624 is another example of the resistor 524 of FIG. 5.

The compensation circuitry 628 has a first terminal, a second terminal, a third terminal, and a fourth terminal. The first terminal of the compensation circuitry 628 is coupled to the supply terminal, which supplies the supply voltage. The second terminal of the compensation circuitry 628 is coupled to the oscillator circuitry 604, 608, the LC tank circuitry 612, and the capacitor 620. The third terminal of the compensation circuitry 628 is coupled to the oscillator circuitry 604, 608, the LC tank circuitry 616, and the capacitor 620. The fourth terminal of the compensation circuitry 628 is coupled to the LC tank circuitry 612, 616 and the resistor 624.

The current source circuitry 630 has a first terminal, a second terminal, and a control terminal. The first terminal of the current source circuitry 630 is coupled to the supply terminal, which supplies the supply voltage. The second terminal of the current source circuitry 630 is coupled to the transistors 632, 634. The control terminal of the current source circuitry 630 is coupled to the data terminal, which supplies the data input signal.

The transistor 632 has a first terminal, a second terminal, and a control terminal. The first terminal of the transistor 632 is coupled to the current source circuitry 630 and the transistor 634. The second terminal of the transistor 632 is coupled to the oscillator circuitry 608, the LC tank circuitry 616, the capacitor 620, the compensation circuitry 628, and the transistor 634. The control terminal of the transistor 632 is coupled to the oscillator circuitry 608, the LC tank circuitry 612, the capacitor 620, the compensation circuitry 628, and the transistor 634.

The transistor 634 has a first terminal, a second terminal, and a control terminal. The first terminal of the transistor 634 is coupled to the current source circuitry 630 and the transistor 632. The second terminal of the transistor 634 is coupled to the oscillator circuitry 608, the LC tank circuitry 612, the capacitor 620, the compensation circuitry 628, and the transistor 632. The control terminal of the transistor 634 is coupled to the oscillator circuitry 608, the LC tank circuitry 616, the capacitor 620, the compensation circuitry 628, and the transistor 632.

The current source circuitry 636 has a first terminal, a second terminal, and a control terminal. The first terminal of the current source circuitry 636 is coupled to the supply terminal, which supplies the supply voltage. The second terminal of the current source circuitry 636 is coupled to the transistors 640, 642. The control terminal of the current source circuitry 636 is coupled to the data terminal, which supplies the digital input signal.

The transistor 640 has a first terminal, a second terminal, and a control terminal. The first terminal of the transistor 640 is coupled to the current source circuitry 636 and the transistor 642. The second terminal of the transistor 642 is coupled to the oscillator circuitry 604, the LC tank circuitry 616, the capacitor 620, the compensation circuitry 628, and the transistor 640. The control terminal of the transistor 640 is coupled to the oscillator circuitry 604, the LC tank circuitry 612, the capacitor 620, the compensation circuitry 628, and the transistor 642.

The transistor 642 has a first terminal, a second terminal, and a control terminal. The first terminal of the transistor 642 is coupled to the current source circuitry 636 and the transistor 640. The second terminal of the transistor 642 is coupled to the oscillator circuitry 604, the LC tank circuitry 612, the capacitor 620, the compensation circuitry 628, and the transistor 640. The control terminal of the transistor 642 is coupled to the oscillator circuitry 604, the LC tank circuitry 616, the capacitor 620, the compensation circuitry 628, and the transistor 640.

The capacitor 644 has a first terminal and a second terminal. The first terminal of the capacitor 644 is coupled to the oscillator circuitry 604, 608, the capacitors 620, 648, the compensation circuitry 628, the resistor 646, and the inductor 150. The second terminal of the capacitor 644 is coupled to the LC tank circuitry 616, the resistors 624, 646, and the compensation circuitry 628. The resistor 646 has a first terminal and a second terminal. The first terminal of the resistor 646 is coupled to the oscillator circuitry 604, 608, the capacitors 620, 644, 648, the compensation circuitry 628, and the inductor 150. The second terminal of the resistor 646 is coupled to the LC tank circuitry 616, the resistor 624, the compensation circuitry 628, and the capacitor 644.

The capacitor 648 has a first terminal and a second terminal. The first terminal of the capacitor 648 is coupled to the oscillator circuitry 604, 608, the capacitors 620, 644, the compensation circuitry 628, the resistor 646, and the inductor 150. The second terminal of the capacitor 648 is coupled to the common terminal, which supplies the common potential. In the example of FIG. 6, the capacitor 648 is an example of a parasitic capacitance formed between bond wires that couple the inductor 150 from one die to another. For example, when the inductor 150 is in the die 245 of FIG. 2 and the transmitter circuitry 600 is in the die 240 of FIG. 2, the capacitor 648 represents a capacitance formed between the bond wires 264A, 264B of FIG. 2. In some examples, the capacitor 648 may not be illustrated or described as a parasitic capacitor.

The capacitor 654 has a first terminal and a second terminal. The first terminal of the capacitor 654 is coupled to the oscillator circuitry 604, 608, the capacitors 620, 658, the compensation circuitry 628, the resistor 656, and the inductor 155. The second terminal of the capacitor 654 is coupled to the LC tank circuitry 612, the resistors 624, 656, and the compensation circuitry 628.

The resistor 656 has a first terminal and a second terminal. The first terminal of the resistor 656 is coupled to the oscillator circuitry 604, 608, the capacitors 620, 654, 658, the compensation circuitry 628, and the inductor 155. The second terminal of the resistor 656 is coupled to the LC tank circuitry 612, the resistor 624, the compensation circuitry 628, and the capacitor 654.

The capacitor 658 has a first terminal and a second terminal. The first terminal of the capacitor 658 is coupled to the oscillator circuitry 604, 608, the capacitors 620, 654, the compensation circuitry 628, the resistor 656, and the inductor 155. The second terminal of the capacitor 658 is coupled to the common terminal, which supplies the common potential. In the example of FIG. 6, the capacitor 658 is an example of an equivalent capacitance formed between bond wires that couple the inductor 155 from one die to another. For example, when the inductor 155 is in the die 245 and the transmitter circuitry 600 is in the die 240, the capacitor 658 represents a capacitance formed between the bond wires 264B, 264C of FIG. 2. In some examples, the capacitor 658 may not be illustrated or described as a parasitic capacitor.

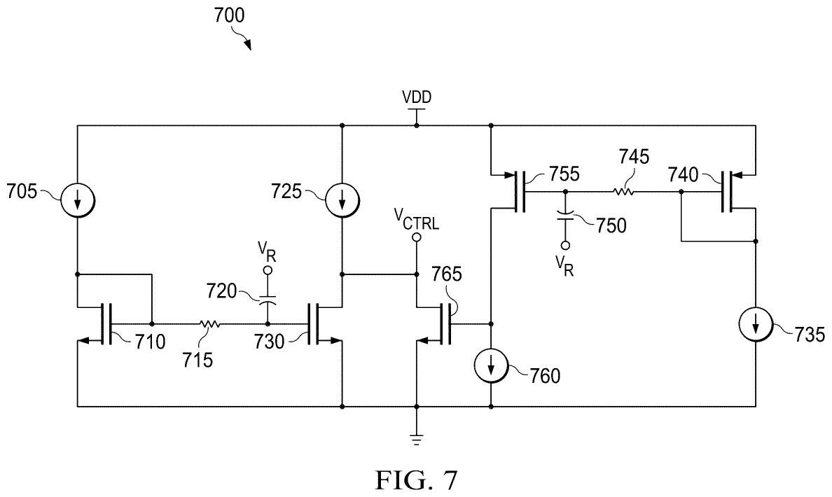

The compensation controller circuitry 664 has a first terminal and a second terminal. The first terminal of the compensation controller circuitry 664 is coupled to the LC tank circuitry 612, 616 and the resistor 624. The second terminal of the compensation controller circuitry 664 is coupled to the current source circuitry 668. An example of the compensation controller circuitry 664 is further illustrated and described in connection with FIG. 7, below.

The current source circuitry 668 has a first terminal, a second terminal, and a control terminal. The first terminal of the current source circuitry 668 is coupled to the supply terminal, which supplies the supply voltage. The second terminal of the current source circuitry 668 is coupled to the transistors 672, 676. The control terminal of the current source circuitry 668 is coupled to the compensation controller circuitry 664.

The transistor 672 has a first terminal, a second terminal, and a control terminal. The first terminal of the transistor 672 is coupled to the current source circuitry 668 and the transistor 676. The second terminal of the transistor 672 is coupled to the oscillator circuitry 604, 608, the LC tank circuitry 616, the capacitor 620, and the transistor 676. The control terminal of the transistor 672 is coupled to the oscillator circuitry 604, 608, the LC tank circuitry 612, the capacitor 620, and the transistor 676.

The transistor 676 has a first terminal, a second terminal, and a control terminal. The first terminal of the transistor 676 is coupled to the current source circuitry 668 and the transistor 672. The second terminal of the transistor 676 is coupled to the oscillator circuitry 604, 608, the LC tank circuitry 612, the capacitor 620, and the transistor 672. The control terminal of the transistor 676 is coupled to the oscillator circuitry 604, 608, the LC tank circuitry 616, the capacitor 620, and the transistor 672.

In the example of FIG. 6, the transistors 632, 634, 640, 642, 672, 676 are p-channel MOSFETs. Alternatively, the transistors 632, 634, 640, 642, 672, 676 may be p-channel FETs, p-channel IGBTs, p-channel JFETs, PNP BJTs or, with slight modifications, n-type equivalent devices. In some examples, the transistors 632, 634, 640, 642, 672, 676 may be depletion mode devices, drain-extended devices, enhancement mode devices, natural transistors, or other type of device structure transistors. Furthermore, the transistors 632, 634, 640, 642, 672, 676 may be implemented in/over a silicon substrate (Si), a silicon carbide substrate (SiC), a gallium nitride substrate (GaN) or a gallium arsenide substrate (GaAs).

In example operation, the resistor 624 reduces mismatches resulting from the non-ideal currents by isolating the capacitors 644, 654 and the resistors 646, 656. In such example operations, the resistor 624 generates a voltage difference responsive to the non-ideal currents. The compensation controller circuitry 664 turns on the current source circuitry 668 responsive to a determination that the voltage difference of the resistor 624 represents non-ideal currents. The transistors 672, 676 supply additional charge to the LC tank circuitry 612, 616 to compensate for the non-ideal currents. Advantageously, the compensation circuitry 628 controls the current source circuitry 668, which supplies additional current to compensate loss of swing for the non-ideal ground currents. The operations of the oscillator circuitry 604, 608 and the LC tank circuitry 612, 616 are similar to in FIGS. 3, 4, and 5 and are described in further detail in connection with FIG. 8, below.

FIG. 7 is a schematic diagram of example compensation controller circuitry 700, which is an example implementation of the compensation controller circuitry 664 of FIG. 6. In the example of FIG. 7, the compensation controller circuitry 700 includes first current source circuitry 705, a first transistor 710, a first resistor 715, a first capacitor 720, second current source circuitry 725, a second transistor 730, third current source circuitry 735, a third transistor 740, a second resistor 745, a second capacitor 750, a fourth transistor 755, fourth current source circuitry 760, and a fifth transistor 765.

The compensation controller circuitry 700 has a first terminal, a second terminal, a third terminal, and a fourth terminal. The first terminal of the compensation controller circuitry 700 is coupled to a supply terminal, which supplies a supply voltage. The second terminal of the compensation controller circuitry 700 is coupled to the common terminal, which supplies the common potential. The third terminal of the compensation controller circuitry 700 is structured to be coupled to blocking or isolating resistors (e.g., the resistors 524, 624 of FIGS. 5 and 6), which supplies a reference voltage (VR). In the example of FIG. 7, the reference voltage represents a voltage difference across the resistors 524, 624. The reference voltage is approximately equal to a resistance of the resistors 524, 624 times a ground current from the common potential of the transmitter circuitry 500, 600 of FIGS. 5 and 6. The fourth terminal of the compensation controller circuitry 700 is structured to be coupled to the current source circuitry 668 of FIG. 6. The compensation controller circuitry 700 is structured to control the current source circuitry 668 of FIG. 6 by generating a control voltage (V_{CTRL}) at the fourth terminal of the compensation controller circuitry 700.

The current source circuitry 705 has a first terminal and a second terminal. The first terminal of the current source circuitry 705 is coupled to the supply terminal, which supplies the supply voltage. The second terminal of the current source circuitry 705 is coupled to the transistor 710 and the resistor 715. The transistor 710 has a first terminal, a second terminal, and a control terminal. The first and control terminals of the transistor 710 are coupled to the current source circuitry 705 and the resistor 715. The second terminal of the transistor 710 is coupled to the common terminal, which supplies the common potential. In the example of FIG. 7, the current source circuitry 705 and the transistor 710 are structured as bias circuitry, which biases the transistors 710, 730 near a subthreshold region of operation. Alternatively, the compensation controller circuitry 700 may be modified to use alternative circuitry to bias the transistor 730.

The resistor 715 has a first terminal and a second terminal. The first terminal of the resistor 715 is coupled to the current source circuitry 705 and the transistor 710. The second terminal of the resistor 715 is coupled to the capacitor 720 and the transistor 730. The capacitor 720 has a first terminal and a second terminal. The first terminal of the capacitor 720 is structured to be coupled to the blocking or isolating resistor (e.g., the resistors 524, 624), which supplies the reference voltage. The second terminal of the capacitor 720 is coupled to the resistor 715 and the transistor 730. The capacitor 720 is structured to control the transistors 710, 730 by filtering the reference voltage. Alternatively, the compensation controller circuitry 700 may be modified or replace the capacitor 720 with alternative filter circuitry.

The current source circuitry 725 has a first terminal and a second terminal. The first terminal of the current source circuitry 725 is coupled to the supply terminal, which supplies the supply voltage. The second terminal of the current source circuitry 725 is coupled to the transistors 730, 765 and is structured to be coupled to the current source circuitry 668. The transistor 730 has a first terminal, a second terminal, and a control terminal. The first terminal of the transistor 730 is coupled to the current source circuitry 725, the transistor 765, and is structured to be coupled to the current source circuitry 668. The second terminal of the transistor 730 is coupled to the common terminal, which supplies the common potential. The control terminal of the transistor 730 is coupled to the resistor 715 and the capacitor 720.

The current source circuitry 735 has a first terminal and a second terminal. The first terminal of the current source circuitry 735 is coupled to the transistor 740 and the resistor 745. The second terminal of the current source circuitry 735 is coupled to the common terminal, which supplies the common potential. The transistor 740 has a first terminal, a second terminal, and a control terminal. The first terminal of the transistor 740 is coupled to the supply terminal, which supplies the supply voltage. The second and control terminals of the transistor 740 are coupled to the current source circuitry 735 and the resistor 745. In the example of FIG. 7, the current source circuitry 735 and the transistor 740 are structured as bias circuitry, which biases the transistors 740, 755 near a subthreshold region of operation. Alternatively, the compensation controller circuitry 700 may be modified to use alternative circuitry to bias the transistor 755.

The resistor 745 has a first terminal and a second terminal. The first terminal of the resistor 745 is coupled to the current source circuitry 735 and the transistor 740. The second terminal of the resistor 745 is coupled to the capacitor 750 and the transistor 755. The capacitor 750 has a first terminal and a second terminal. The first terminal of the capacitor 750 is structured to be coupled to the blocking or isolating resistor (e.g., the resistors 524, 624), which supplies the reference voltage. The second terminal of the capacitor 750 is coupled to the resistor 745 and the transistor 755. The capacitor 750 is structured to control the transistors 740, 755 by filtering the reference voltage. Alternatively, the compensation controller circuitry 700 may be modified or replace the capacitor 750 with alternative filter circuitry.

The transistor 755 has a first terminal, a second terminal, and a control terminal. The first terminal of the transistor 755 is coupled to the supply terminal, which supplies the supply voltage. The second terminal of the transistor 755 is coupled to the current source circuitry 760 and the transistor 765. The control terminal of the transistor 755 is coupled to the resistor 745 and the capacitor 750. The current source circuitry 760 has a first terminal and a second terminal. The first terminal of the current source circuitry 760 is coupled to the transistors 755, 765. The second terminal of the current source circuitry 760 is coupled to the common terminal, which supplies the common potential. In the example of FIG. 7, the transistor 755 and the current source circuitry 760 are structured as bias circuitry, which controls the transistors 765. Alternatively, the compensation controller circuitry 700 may be modified to use alternative circuitry to control the transistor 765.

The transistor 765 has a first terminal, a second terminal, and a control terminal. The first terminal of the transistor 765 is coupled to the current source circuitry 725, the transistor 730, and is structured to be coupled to the current source circuitry 668. The second terminal of the transistor 765 is coupled to the common terminal, which supplies the common potential. The control terminal of the transistor 765 is coupled to the transistor 755 and the current source circuitry 760. Example operations of the compensation controller circuitry 700 are described in connection with FIG. 8, below.

In the example of FIG. 7, the transistors 710, 730, 765 are n-channel MOSFETs. Alternatively, the transistors 710, 730, 765 may be n-channel FETs, n-channel IGBTs, n-channel JFETs, NPN BJTs or, with slight modifications, p-type equivalent devices. In the example of FIG. 7, the transistors 740, 755 are p-channel MOSFETs. Alternatively, the transistors 740, 755 may be p-channel FETs, p-channel IGBTs, p-channel JFETs, PNP BJTs or, with slight modifications, n-type equivalent devices. In some examples, the transistors 710, 730, 740, 755, 765 may be depletion mode devices, drain-extended devices, enhancement mode devices, natural transistors, or other type of device structure transistors. Furthermore, the transistors 710, 730, 740, 755, 765 may be implemented in/over a silicon substrate (Si), a silicon carbide substrate (SiC), a gallium nitride substrate (GaN) or a gallium arsenide substrate (GaAs).

FIG. 8 is a flowchart representative of example operations 800 that may be at least one of executed, instantiated, or performed using an example implementation of the transmitter circuitry 120, 300, 400, 500, 600 of FIGS. 1, 3, 4, 5, and 6 to transmit data across an isolation transformer 130 of FIG. 1. The example operations 800 of FIG. 8 begin at Block 805 at which the transmitter circuitry 120, 300, 400, 500, 600 receives data to transmit. (Block 805). In some examples, the communication channels 110, 115 of FIG. 1 receive a digital signal from the programmable circuitry 105 of FIG. 1. In such examples, the digital signal represents data that the transmitter circuitry 120, 300, 400, 500, 600 is to transmit across the isolation transformer 130 to the receiver circuitry 135. Advantageously, transmitting data across the isolation transformer 130 allows the programmable circuitry 105 to operate using different supply voltages in comparison with circuitry coupled to the receiver circuitry 135.

The oscillator circuitry 140, 145, 305, 310, 404, 408, 504, 508, 604, 608 of FIGS. 1, 3, 4, 5, and 6 is structured responsive to whether the data is a logic one. (Block 810). In some examples, the logical state of the digital input signal controls the current source circuitry 330, 345, 530, 536, 630, 636 of FIGS. 3, 5, and 6. In other examples, the logical state of the digital input signal controls the bias circuitry 424 of FIG. 4. In such examples, the bias circuitry 424 controls the transistors 428, 440 of FIG. 4, similar to the current source circuitry 330, 345, 530, 536, 630, 636. Also, the current source circuitry 330, 345, 530, 536, 630, 636 may be implemented using transistors and bias circuitry, as shown in FIG. 4.

If the data is not a logic one (e.g., Block 810 returns a result of NO), the current source circuitry 330, 345, 530, 536, 630, 636 and the transistors 428, 440 prevent a supply of current. (Block 815). When the transmitter circuitry 120, 300, 400, 500, 600 is structured to implement OOK modulation, a logic zero of the digital signal is represented by a lack of a modulated signal. In some examples, when the logic state of the digital signal is a logic zero, the digital signal turns off the current source circuitry 330, 345, 530, 536, 630, 636. In such examples, the oscillator circuitry 305, 310, 504, 508, 604, 608 are structured to prevent a supply of additional current. In other examples, when the logic state of the digital signal is a logic zero, the digital signal opens the switch 484 of FIG. 4 and closes the switch 488 of FIG. 4. In such examples, the bias circuitry 424 prevents the oscillator circuitry 404, 408 from supplying additional current by coupling the control terminals of the transistors 428, 440, which are p-channel transistors, to the supply terminal.

If the data is a logic one (e.g., Block 810 returns a result of YES), the current source circuitry 330, 530, 630, and the transistor 428 supply a first current to a first pair of transistors. (Block 820). When the transmitter circuitry 120, 300, 400, 500, 600 is structured to implement OOK modulation, a logic one of the digital signal is represented by generating a sinusoidal signal, which is a modulated representation of the logic one. In some examples, when the logic state of the digital signal is a logic one, the digital signal turns on the current source circuitry 330, 530, 630. In other examples, when the logic state of the digital signal is a logic one, the digital signal closes the switch 484 and opens the switch 488. In such examples, the bias circuitry 424 structures the transistor 428 to conduct current.

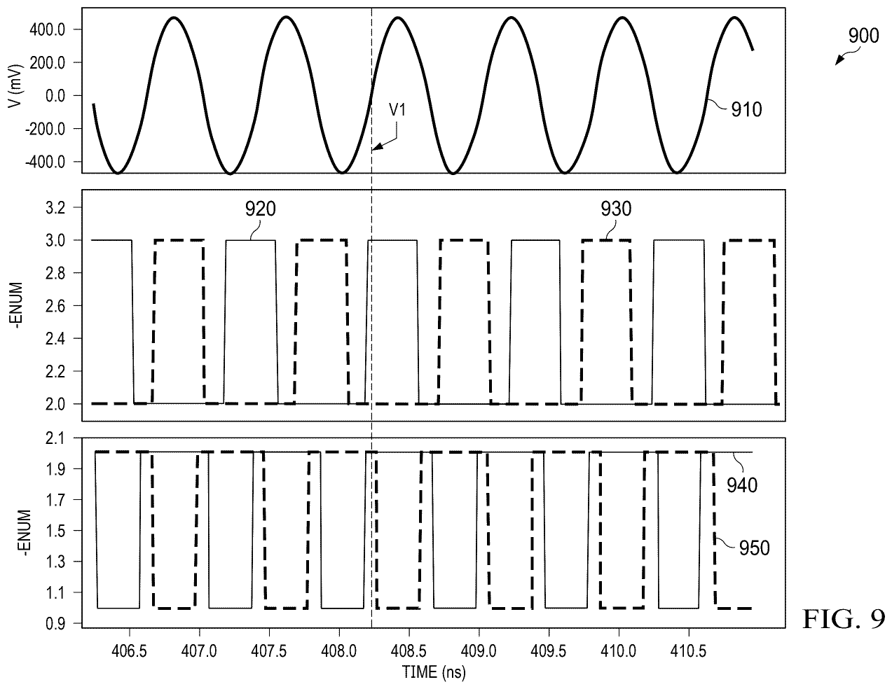

The transistors 335, 340, 432, 436, 532, 534, 632, 634 of FIGS. 3, 4, 5, and 6 provide the first current using low threshold voltage transistors. (Block 825). In some examples, the transistors 335, 340, 432, 436, 532, 534, 632, 634 are low threshold voltage (LVT) transistors. Low threshold voltage transistors are a class of transistors that have a reduced threshold voltage. For example, some transistors have a threshold voltage of approximately seven-tenths of a volt and low threshold voltage transistors have a threshold voltage of approximately four-tenths of a volt. Advantageously, the low threshold voltage allows the transistors 335, 340, 432, 436, 532, 534, 632, 634 to switch between saturation and linear regions of operation during modulation. Example switching between modes of operation of the transistors 335, 340, 432, 436, 532, 534, 632, 634 are illustrated and described in connection with FIG. 9, below. However, when the transistors 335, 340, 432, 436, 532, 534, 632, 634 are low threshold voltage transistors, the transistors 335, 340, 432, 436, 532, 534, 632, 634 also have a relatively low transconductance. Reducing the transconductance decreases the current swing between the transistors 335, 340, 432, 436, 532, 534, 632, 634 during modulation.

The current source circuitry 345, 536, 636 and the transistor 440 supply a second current to a second pair of transistors. (Block 830). When the transmitter circuitry 120, 300, 400, 500, 600 is structured to implement OOK modulation, a logic one of the digital signal is represented by generating a sinusoidal signal, which is a modulated representation of the logic one. In some examples, when the logic state of the digital signal is a logic one, the digital signal turns on the current source circuitry 345, 536, 636. In other examples, when the logic state of the digital signal is a logic one, the digital signal closes the switch 484 and opens the switch 488. In such examples, the bias circuitry 424 structures the transistor 440 to conduct current.

The transistors 350, 355, 444, 448, 538, 540, 640, 642 of FIGS. 3, 4, 5, and 6 provide the second current using high threshold voltage transistors. (Block 835). In some examples, the transistors 350, 355, 444, 448, 538, 540, 640, 642 are high threshold voltage transistors (also referred to as high performance transistors). High performance transistors are a class of transistors that are designed for power efficiency and have a threshold voltage higher than low threshold voltage transistors. Example switching between regions of operation of the transistors 350, 355, 444, 448, 538, 540, 640, 642 are illustrated and described in connection with FIG. 9, below Advantageously, the transistors 350, 355, 444, 448, 538, 540, 640, 642 have a transconductance that is higher than the transistors 335, 340, 432, 436, 532, 534, 632, 634. Advantageously, the relatively high transconductance of the transistors 350, 355, 444, 448, 538, 540, 640, 642 increases the current swing between the transistors 350, 355, 444, 448, 538, 540, 640, 642 during modulation.

The LC tank circuitry 315, 412, 512, 612 of FIGS. 3, 4, 5, and 6 drive a P-side inductance using currents from the first and second pairs of transistors. (Block 840). In some examples, the LC tank circuitry 315, 412, 512, 612 generates a sinusoidal signal across the inductor 150 of FIGS. 1, 3, 4, 5, and 6 responsive to currents from the oscillator circuitry 140, 145, 305, 310, 404, 408, 504, 508, 604, 608. In such examples, the frequency of the sinusoidal signal is approximately equal to a resonant frequency of the LC tank circuitry 315, 412, 512, 612, which is determined by the inductance of the inductor 150 and the capacitance of the capacitors 360, 452, 544, 644 of FIGS. 3, 4, 5, and 6. Advantageously, the sinusoidal signal of the LC tank circuitry 315, 412, 512, 612 controls the transistors 335, 355, 432, 444, 532, 538, 632, 640, which provide current to the LC tank circuitry 320, 416, 516, 616 of FIGS. 3, 4, 5, and 6.

The LC tank circuitry 320, 416, 516, 616 of FIGS. 3, 4, 5, and 6 drive an M-side inductance using currents from the first and second pairs of transistors. (Block 850). In some examples, the LC tank circuitry 320, 416, 516, 616 generates a sinusoidal signal across the inductor 155 of FIGS. 1, 3, 4, 5, and 6 responsive to currents from the oscillator circuitry 140, 145, 305, 310, 404, 408, 504, 508, 604, 608. In such examples, the frequency of the sinusoidal signal is approximately equal to a resonant frequency of the LC tank circuitry 320, 416, 516, 616, which is determined by the inductance of the inductor 155 and the capacitance of the capacitors 375, 464, 554, 654 of FIGS. 3, 4, 5, and 6. Advantageously, the sinusoidal signal of the LC tank circuitry 320, 416, 516, 616 controls the transistors 340, 350, 436, 448, 534, 540, 642, 634 to regulate the supply of current to the LC tank circuitry 315, 412, 512, 612.

The resistors 365, 380, 456, 468, 546, 556, 646, 656 of FIGS. 3, 4, 5, and 6 compensate the P-side and M-side inductances for mismatches. (Block 855). In some examples, the resistors 365, 380, 456, 468, 546, 556, 646, 656 are coupled in parallel with the inductors 150, 155. In such examples, the resistors 365, 380, 456, 468, 546, 556, 646, 656 are intentionally selected to be lower than the equivalent resistances of the inductors 150, 155. For example, when the inductor 150 have an equivalent resistance of six-hundred and sixty-five ohms (Ω) and the inductors 155 have an equivalent resistance of six-hundred and eighty-eight ohms, the resistors 365, 380, 456, 468, 546, 556, 646, 656 are selected to have a resistance of five-hundred ohms. In such examples, coupling the resistors 365, 380, 456, 468, 546, 556, 646, 656 in parallel creates effective resistances that have a five-ohm difference in comparison to the original mismatch of twenty-two ohms between the equivalent resistances. In another example, when the inductor 150 have an equivalent resistance of six-hundred and sixty-five ohms and the inductor 155 have an equivalent resistance of six-hundred and eighty-eight ohms, the resistors 365, 380, 456, 468, 546, 556, 646, 656 are selected to have a resistance of two-hundred and fifty ohms. In such examples, coupling the resistors 365, 380, 456, 468, 546, 556, 646, 656 in parallel creates effective resistances that have about a two-ohm difference in comparison to the original mismatch of twenty-two ohms between the equivalent resistances.

Advantageously, the resistors 365, 380, 456, 468, 546, 556, 646, 656 reduce the mismatch between the equivalent resistances of the inductors 150, 155. Advantageously, reducing the mismatch between the equivalent resistances of the inductors 150, 155 reduces mismatch between currents of the oscillator circuitry 140, 145, 305, 310, 404, 408, 504, 508, 604, 608. Advantageously, reducing mismatch between currents of the oscillator circuitry 140, 145, 305, 310, 404, 408, 504, 508, 604, 608 reduces the radiated emissions.

The compensation controller circuitry 664, 700 of FIGS. 6 and 7 detects common mode noise through the P-side and M-side inductances. (Block 860). In some examples, the compensation controller circuitry 664, 700 detects common mode noise based on the voltage difference across the resistors 524, 624 of FIGS. 5 and 6. In such examples, the resistors 524, 624 generate a voltage difference responsive to non-ideal currents from the ground path circuitry 528 of FIG. 5. Such non-ideal currents of a common potential result from components of the implementing of the communication channels 110, 115 in a device, such as the device 200 of FIG. 2. For example, as further described above in connection FIG. 5, components of the device 200 form the ground path circuitry 528. Advantageously, the resistors 524, 624 reduce the impact of the non-ideal currents by blocking the current path to the capacitors 544, 554, 644, 654 and the resistors 546, 556, 646, 656. Advantageously, the resistors 524, 624 allow the compensation controller circuitry 664, 700 to detect the non-ideal currents.

The compensation controller circuitry 664, 700 determines if there is common mode noise. (Block 865). In some examples, the transistor 710 of FIG. 7 biases the transistor 730, which conducts a current equal to the current from the current source circuitry 705 of FIG. 7. Similarly, the transistor 740 of FIG. 7 biases the transistor 755 of FIG. 7, which conducts a current equal to the current of the current source circuitry 735 of FIG. 7. The current of the current source circuitry 760 of FIG. 7 is designed to be larger than the current of the current source circuitry 735, which allows the current source circuitry 760 to pull down the control terminal of the transistor 765. The current of the current source circuitry 725 of FIG. 7 is designed to be larger than the current of the current source circuitry 705, 735, which allows the current source circuitry 725 to pull up the control voltage (V_{CTRL}).

In example operation, when a ground current across the resistors 524, 624 increases the reference voltage (also referred to as a positive ground current), the reference voltage increases the voltage at the control terminal of the transistor 730. The transistor 730 begins to sink additional current, which pulls down the control voltage.

In such example operations, when a ground current across the resistors 524, 624 decreases the reference voltage (also referred to as a negative ground current), the reference voltage decreases the voltage at the control terminal of the transistor 755. The transistor 755 begins to sink additional current responsive to an increase in the gate-to-source voltage of the transistor 755. The additional current from the transistor 755 pulls up the voltage at the control terminal of the transistor 765. The transistor 765 begins to conduct current responsive to the additional current from the transistor 755. The transistor 765 pulls down the control voltage responsive to conducting current.

Advantageously, the control voltage of the compensation controller circuitry 664, 700 is approximately equal to the supply voltage when the reference voltage is approximately equal to the common potential. Advantageously, the control voltage of the compensation controller circuitry 664, 700 is approximately equal to the common potential when the reference voltage is not equal to the common potential.

If the compensation controller circuitry 664, 700 determines that there is no common mode noise (e.g., Block 865 returns a result of NO), control proceeds to return to Block 805. In some examples, the resistors 524, 624 generate a reference voltage approximately equal to the common potential when non-ideal ground currents are not present. In such examples, the compensation controller circuitry 664, 700 turns off the current source circuitry 668 to prevent a compensation current from being supplied.

If the compensation controller circuitry 664, 700 determines that there is common mode noise (e.g., Block 865 returns a result of YES), the compensation circuitry 628 of FIG. 6 compensates for the common mode noise. (Block 870). In some examples, the compensation controller circuitry 664, 700 adjusts the control voltage responsive to the resistors 524, 624 generating a reference voltage representing non-ideal ground currents. In such examples, the compensation controller circuitry 664, 700 turns on the current source circuitry 668, which supplies current to the transistors 672, 676 of FIG. 6. Advantageously, the transistors 672, 676 supply excess current to the LC tank circuitry 612, 616 to compensate for non-ideal ground currents. Advantageously, compensating for the non-ideal ground currents further improves radiated immunity. Control proceeds to return to Block 805.

Although example methods are described with reference to the flowchart illustrated in FIG. 8, many other methods of implementing the transmitter circuitry 120, 300, 400, 500, 600 of FIGS. 1, 3, 4, 5, and 6, or more generally the communication channel 110 of FIG. 1 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

FIG. 9 is a timing diagram 900 of example operations of the transmitter circuitry 120, 300, 400, 500, 600 of FIGS. 1, 3, 4, 5, and 6. In the example of FIG. 9, the timing diagram 900 includes an oscillator output signal 910, a first high performance transistor region of operation 920, a second high performance transistor mode of operation 930, a first low threshold voltage transistor mode of operation 940, and a second low threshold voltage transistor mode of operation 950. The oscillator output signal 910 illustrates a modulated signal across the inductors 150, 155 of FIGS. 1, 3, 4, 5, and 6 when a logic one is to be transmitted across the isolation transformer 130 of FIG. 1. In the example of OOK modulation, the oscillator output signal 910 is a sinusoidal signal.

The high-performance transistor mode of operation 920 illustrates a state of operation of the transistors 355, 444, 538, 640 of FIGS. 3, 4, 5, and 6 during operations to produce the oscillator output signal 910. The oscillation of the LC tank circuitry 315, 412, 512, 612 of FIGS. 3, 4, 5, and 6 controls the state of operation of the transistors 355, 444, 538, 640. The high-performance transistor mode of operation 930 illustrates a region of operation of the transistors 350, 448, 540, 642 of FIGS. 3, 4, 5, and 6 during operations to produce the oscillator output signal 910. The oscillation of the LC tank circuitry 320, 416, 516, 616 of FIGS. 3, 4, 5, and 6 controls the region of operation of the transistors 350, 448, 540, 642.

In the example of FIG. 9, the high-performance transistor mode of operation 920, 930 switches between a subthreshold mode (2) and a saturation mode (3). When in the subthreshold mode, the transistors 350, 355, 444, 448, 538, 540, 640, 642 conduct a relatively small and limited current. Advantageously, operating the transistors 350, 355, 444, 448, 538, 540, 640, 642 in subthreshold and saturation modes of operation allows for relatively large swing currents. However, the relatively high transconductance and threshold voltage of the transistors 350, 355, 444, 448, 538, 540, 640, 642 result in durations of time where only one of the transistors 350, 355, 444, 448, 538, 540, 640, 642 are conducting current (e.g., both of the high-performance transistor mode of operation 920, 930 are in subthreshold mode). Advantageously, as further described below, the transistors 335, 340, 432, 436, 532, 534, 632, 634 reduce emissions by reducing variations in the tail node (e.g., tail noise) by continuing to conduct current throughout the swing of the LC tank circuitry 315, 320, 412, 416, 512, 516, 612, 616, which reduces the currents through the transistors 350, 355, 444, 448, 538, 540, 640, 642.

The low threshold voltage transistor mode of operation 940 illustrates a state of operation of the transistors 335, 432, 532, 632 of FIGS. 3, 4, 5, and 6 during operations to produce the oscillator output signal 910. The oscillation of the LC tank circuitry 315, 412, 512, 612 controls the state of operation of the transistors 335, 432, 532, 632. The low threshold voltage transistor mode of operation 950 illustrates a state of operation of the transistors 340, 436, 534, 634 of FIGS. 3, 4, 5, and 6 during operations to produce the oscillator output signal 910. The oscillation of the LC tank circuitry 320, 416, 516, 616 controls the state of operation of the transistors 340, 436, 534, 634.

In the example of FIG. 9, the low threshold voltage transistor mode of operation 940, 950 switch between a linear mode (1) and a saturation mode (2). When in the linear mode and saturation mode, the transistors 335, 340, 432, 436, 532, 534, 632, 634 conduct current. Advantageously, using low threshold voltages to switch the transistors 335, 340, 432, 436, 532, 534, 632, 634 between subthreshold and linear modes of operation allows the oscillator circuitry 305, 404, 504, 604 to continuously conduct current throughout the swing of current. Advantageously, operating the transistors 335, 340, 432, 436, 532, 534, 632, 634 in subthreshold and linear modes of operation prevents tail node variations, which reduces radiated emissions. However, the relatively low transconductance of the transistors 335, 340, 432, 436, 532, 534, 632, 634 the resulting current swing in weak corners is relatively small. Advantageously, using a combination of high-performance transistors and low threshold voltage transistors decreases radiated emissions and compensates for weak corner swing.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

Modifications are possible in the described embodiments, and other embodiments are possible, within the scope of the claims.

What is claimed is:

1. An apparatus comprising:
first current source circuitry having a terminal;
second current source circuitry having a terminal;
a first transistor having a first terminal, a second terminal, and a control terminal;
a second transistor having a first terminal, a second terminal, and a control terminal, the first terminal of the second transistor coupled to the terminal of the first current source circuitry and the first terminal of the first transistor;
a third transistor having a first terminal, second terminal, and a control terminal;
a fourth transistor having a first terminal, a second terminal, and a control terminal, the first terminal of the fourth transistor coupled to the terminal of the second current source circuitry and the first terminal of the third transistor; and
inductor circuitry having a first terminal and a second terminal, the first terminal of the inductor circuitry coupled to the second terminal of the first transistor, the control terminal of the second transistor, the second terminal of the third transistor, and the control terminal of the fourth transistor, the second terminal of the inductor circuitry coupled to the control terminal of the first transistor, the second terminal of the second transistor, the control terminal of the third transistor, and the second terminal of the fourth transistor.

2. The apparatus of claim 1, wherein the inductor circuitry including
a first inductor having a first terminal and a second terminal, the first terminal of the first inductor is coupled to the second terminal of the first transistor, the control terminal of the second transistor, the second terminal of the third transistor, and the control terminal of the fourth transistor; and
a second inductor having a first terminal and a second terminal, the first terminal of the second inductor is coupled to the control terminal of the first transistor, the second terminal of the second transistor, the control terminal of the third transistor, and the second terminal of the fourth transistor, the second terminal of the second inductor is coupled to the second terminal of the first inductor.

3. The apparatus of claim 2, further comprising:
a first resistor having a first terminal and a second terminal, the first terminal of the first resistor is coupled to the second terminal of the first transistor, the control terminal of the second transistor, the second terminal of the third transistor, the control terminal of the fourth transistor, and the first terminal of the first inductor, the second terminal of the first resistor is coupled to the second terminal of the first inductor; and
a second resistor having a first terminal and a second terminal, the first terminal of the second resistor is coupled to the control terminal of the first transistor, the second terminal of the second transistor, the control terminal of the third transistor, the second terminal of the fourth transistor, and the first terminal of the second inductor, the second terminal of the second resistor is coupled to the second terminal of the second inductor.

4. The apparatus of claim 3, further comprising a third resistor having a first terminal and a second terminal, the first terminal of the third resistor is coupled to the second terminal of the first inductor and the second terminal of the second inductor, the second terminal of the third resistor is coupled to the second terminal of the first resistor and the second terminal of the second resistor.

5. The apparatus of claim 1, wherein the first current source circuitry includes a fifth transistor having a first terminal, a second terminal, and a control terminal, the first terminal of the fifth transistor is coupled to the first terminal of the first transistor and the first terminal of the second transistor, the second current source circuitry includes a sixth transistor having a first terminal and a control terminal, the first terminal of the sixth transistor is coupled to the first terminal of the third transistor and the first terminal of the fourth transistor, the second terminal of the sixth transistor coupled to the second terminal of the fifth transistor, the control terminal of the sixth transistor coupled to the control terminal of the fifth transistor.

6. The apparatus of claim 5, the apparatus further comprising bias circuitry including:
third current source circuitry having a terminal;
a seventh transistor having a first terminal and a control terminal; and
switch circuitry having a first terminal and a second terminal, the first terminal of the switch circuitry is coupled to the terminal of the third current source circuitry, the first terminal of the seventh transistor, and the control terminal of the seventh transistor, the second terminal of the switch circuitry is coupled to the control terminal of the fifth transistor and the control terminal of the sixth transistor.

7. The apparatus of claim 1, wherein the first and second transistors have a first threshold voltage and a first transconductance, the second and third transistors have a second threshold voltage and a second transconductance, the first threshold voltage is greater than the second threshold voltage, and the first transconductance is greater than the second transconductance.

8. The apparatus of claim 1, wherein the inductor circuitry is first inductor circuitry, and the apparatus further comprising:
second inductor circuitry electromagnetically coupled to the first inductor circuitry; and
receiver circuitry coupled to the second inductor circuitry.

9. An apparatus comprising:
first oscillator circuitry having a first terminal, a second terminal, and including a first transistor having a first threshold voltage;
second oscillator circuitry having a first terminal, a second terminal, and including a second transistor having a second threshold voltage, the second threshold voltage is less than the first threshold voltage;
a first resistor having a first terminal and a second terminal, the first terminal of the first resistor coupled to the first terminal of the first oscillator circuitry and the first terminal of the second oscillator circuitry;
a second resistor having a first terminal and a second terminal, the first terminal of the second resistor coupled to the second terminal of the first oscillator circuitry and the second terminal of the second oscillator circuitry; and
a common terminal coupled to the second terminal of the first resistor and the second terminal of the second resistor.

10. The apparatus of claim 9, further comprising:
a first inductor having a first terminal and a second terminal, the first terminal of the first inductor coupled to the first terminal of the first oscillator circuitry, the first terminal of the second oscillator circuitry, and the first terminal of the first resistor; and
a second inductor having a first terminal and a second terminal, the first terminal of the second inductor coupled to the second terminal of the first oscillator circuitry, the second terminal of the second oscillator circuitry, and the first terminal of the second resistor, the second terminal of the second inductor is coupled to the second terminal of the first resistor, the second terminal of the second resistor, the second terminal of the first inductor, and the common terminal.

11. The apparatus of claim 9, wherein the first oscillator circuitry includes:
current source circuitry having a terminal;
a first transistor having a first terminal, a second terminal, and a control terminal; and
a second transistor having a first terminal, a second terminal, and a control terminal, the first terminal of the second transistor is coupled to the terminal of the current source circuitry and the first terminal of the first transistor, the second terminal of the second transistor is coupled to the first terminal of the second oscillator circuitry, the first terminal of the first resistor, and the control terminal of the first transistor, the control terminal of the second transistor is coupled to the second terminal of the second oscillator circuitry, the first terminal of the second resistor, and the second terminal of the first transistor.

12. The apparatus of claim 11, wherein the second oscillator circuitry further having a third terminal, the current source circuitry is first current source circuitry, the current source circuitry is a third transistor having a first terminal and a control terminal, the first terminal of the third transistor is coupled to the first terminal of the first transistor and the first terminal of the second transistor, and the apparatus further comprising:
second current source circuitry having a terminal;
a fourth transistor having a first terminal and a control terminal; and
switch circuitry having a first terminal, a second terminal, and a control terminal, the first terminal of the switch circuitry is coupled to the terminal of the second current source circuitry, the first terminal of the fourth transistor, and the control terminal of the fourth transistor, the second terminal of the switch circuitry is coupled to the third terminal of the second oscillator circuitry and the control terminal of the third transistor.

13. The apparatus of claim 9, further comprising:
a first capacitor having a first terminal and a second terminal, the first terminal of the first capacitor coupled to the first terminal of the first oscillator circuitry, the first terminal of the second oscillator circuitry, and the first terminal of the first resistor; and
a second capacitor having a first terminal and a second terminal, the first terminal of the second capacitor is coupled to the second terminal of the first oscillator circuitry, the second terminal of the second oscillator circuitry, and the first terminal of the second resistor, the second terminal of the second capacitor is coupled to the second terminal of the first inductor, the second terminal of the second resistor, the common terminal, and the second terminal of the first capacitor.

14. The apparatus of claim 9, further comprising a capacitor having a first terminal and a second terminal, the first terminal of the capacitor is coupled to the first terminal of the first oscillator circuitry, the first terminal of the second oscillator circuitry, and the first terminal of the first resistor, the second terminal of the capacitor is coupled to the second terminal of the first oscillator circuitry, the second terminal of the second oscillator circuitry, and the first terminal of the second resistor.

15. The apparatus of claim 9, wherein the first inductor and the second inductor are first inductor circuitry, the apparatus further comprising:
second inductor circuitry electromagnetically coupled to the first resistor; and
receiver circuitry coupled to the second resistor.

16. An apparatus comprising:
a first transistor having a first terminal, a second terminal, and a control terminal;
a second transistor having a first terminal, a second terminal, and a control terminal, the first terminal of the second transistor coupled to the first terminal of the first transistor;
a third transistor having a first terminal, a second terminal, and a control terminal;
a fourth transistor having a first terminal, a second terminal, and a control terminal, the first terminal of the fourth transistor coupled to the first terminal of the third transistor;
a first resistor having a first terminal and a second terminal, the first terminal of the first resistor coupled to the second terminal of the first transistor, the control terminal of the second transistor, the second terminal of the third transistor, and the control terminal of the fourth transistor;
a second resistor having a first terminal and a second terminal, the first terminal of the second resistor coupled to the control terminal of the first transistor, the second terminal of the second transistor, the control terminal of the third transistor, and the second terminal of the fourth transistor; and
a common terminal coupled to the second terminal of the first resistor and the second terminal of the second resistor.

17. The apparatus of claim 16, wherein the first transistor and the second transistor further have a first transconductance, the third transistor and fourth transistor further have a second transconductance, and the first transconductance is greater than the second transconductance.

18. The apparatus of claim 16, further comprising:
a first inductor having a first terminal and a second terminal, the first terminal of the first inductor is coupled to the second terminal of the first transistor, the control terminal of the second transistor, the second terminal of the third transistor, the control terminal of the fourth transistor, and the first terminal of the first resistor;
a second inductor having a first terminal and a second terminal, the first terminal of the second inductor is coupled to the control terminal of the first transistor, the second terminal of the second transistor, the control terminal of the third transistor, the second terminal of the fourth transistor, and the first terminal of the second resistor; and
a third resistor having a first terminal and a second terminal, the first terminal of the third resistor is coupled to the second terminal of the first resistor and the second terminal of the fourth resistor, the second terminal of the first resistor is coupled to the second terminal of the first inductor and the second terminal of the second inductor.

19. The apparatus of claim 18, further comprising:
a third inductor having a first terminal and a second terminal, the third inductor magnetically coupled to the first inductor and the second inductor;
receiver circuitry having a first terminal and a second terminal, the first terminal of the receiver circuitry is coupled to the third inductor and the second terminal of the receiver circuitry is coupled to second terminal of the third inductor.

20. The apparatus of claim 16, wherein the first transistor, the second transistor, the third transistor, the fourth transistor, the first resistor, and the second resistor are a first communication channel, and the apparatus further comprising a second communication channel.
